(19) United States
(12) Patent Application Publication
(10) Pub. No.: US 2012/0128896 A1
(43) Pub. Date: May 24, 2012

(54) STAIN-RESISTANT CONTAINER AND METHOD

(76) Inventors: Edward B. Tucker, Yorkville, IL (US); John T. Felts, Alameda, CA (US); David K. Heitman, Orlano Park, IL (US)

(21) Appl. No.: 12/950,760

(22) Filed: Nov. 19, 2010

(51) Int. Cl. C23C 16/513; C23C 16/40

(52) U.S. Cl. 427/579; 118/723 R

(57) ABSTRACT

Stain resistant containers can be prepared in a three step process involving treatment with a nitrogen gas plasma, depositing a plasma enhanced chemical vapor deposition (PECVD) organosilicon thin film onto the interior surface of the container, followed by treatment with an oxygen gas plasma. An apparatus for the process is described, including an automated apparatus for treating multiple containers and multiple chambers of containers.

### FIELD OF THE INVENTION

The present invention relates generally to containers, and, more particularly, to containers which are stain resistant and a process for manufacturing stain resistant containers via chemical vapor deposition of a thin film onto the interior surface of a container.

### BACKGROUND OF THE INVENTION

Rigid, thermoplastic food containers are generally known. For example, they are described in U.S. Pat. App. 2007/0119743 to Tucker et al. However conventional containers are subject to staining, at which time their value to consumers is decreased and consumers may discard the containers.

Various methods have been developed to reduce staining in these containers. For example, in U.S. Pat. App. 20030015530 to Shepler et al. and U.S. Pat. App. 20020182352 to Mitten et al. a multilayer container gives acceptable performance. For additional examples, in U.S. Pat. No. 5,298,587 to Hu et al. the article is coated with a plasma generated polymer. An apparatus and method of applying the plasma generated polymer is described in U.S. Pat. Nos. 6,015,595, 6,112,695, and 6,180,191 to Felts, U.S. Pat. No. 5,378,510 to Thomas et al., and U.S. Pat. App. 2007/0281108 to Weikart et al. Although these methods can increase the stain resistance of food containers, what is needed is an inexpensive method to produce stain resistant food containers.

### SUMMARY OF THE INVENTION

In accordance with the present invention, a method and apparatus for depositing a thin film onto a surface of a single or multiple containers, a method of improving durability of the containers by selection of preferred container materials, and the resulting container is presented.

The apparatus for chemical deposition includes a chamber made of an electrically insulating material. Located adjacent an exterior surface of the chamber is a main electrode. Extending into the chamber is at least one counter electrode which is a hollow tube that also serves as a gas inlet. In one embodiment, the chamber is sealed on a first end with a chamber door and on a second end with a face plate. The face plate is fitted with a vent port capable of being connected to a vent valve and with a pressure port capable of being connected to a pressure measuring device. The apparatus further includes a pumping plenum attached on a first end to the face plate and a T-coupler attached on a first end to a second end of the pumping plenum. The counter electrode extends through the pumping plenum and through the T-coupler. A vacuum seal is formed between the counter electrode and a second end of the T-coupler. The T-coupler is made of an electrically insulating material thus electrically isolating the counter electrode from the pumping plenum, the face plate and the chamber. Also coupled to the T-coupler is a vacuum pump which is capable of creating a vacuum inside of the chamber. In another embodiment especially suited to coating multiple containers simultaneously, the interior chamber is dimensioned to allow for placement of multiple containers. In this embodiment, a pumping plenum is attached directly to the faceplate. The faceplate also includes locations for more than one counter electrode such that the electrode is not required to extend through the pumping plenum. The face plate also has at least one gas inlet port that comprises a counter electrode that is connected to a first process gas source, a second process gas source, and a third process gas source. A first flow controller is coupled between the gas inlet port and the first process gas source. The first flow controller has the capability of controlling the flow of gas from the first process gas source to the chamber. Connected to the counter electrode is a second process gas source. The second gas component source is a container of organosilicon liquid. A vaporizer/flow controller system (VF system) is provided to vaporize the organosilicon liquid into organosilicon vapor and to control the flow rate of the organosilicon vapor generated. The VF system includes a first valve, a second valve and a capillary tube coupled on a first end to the first valve and on a second end to the second valve. The capillary tube has an inside diameter typically in the range of 0.001 inches to 0.010 inches. The first valve is also coupled to the counter electrode and the second valve is also coupled to a liquid line which is inserted into the container of organosilicon liquid. Also connected to the counter electrode is a third gas source. A third flow controller is coupled between the gas inlet port and the third process gas source. Using this scheme, either the first, second or third gas sources can be introduced into the chamber through the gas inlet, either alone or in combination. In all of the equipment descriptions herein, capillary tubes with inside diameters ranging from 0.001″ to 0.010″ can be used interchangeably with flow meters. The main electrode and counter electrode are powered by an alternating current (AC) power supply which preferably has an output frequency of 13.56 megahertz (MHz). In one embodiment, to allow a container to be readily mounted in the chamber, a mandrel is mounted on the counter electrode. The mandrel has a lip on to which the container can be sealingly mounted. Extending through the mandrel are one or more gas outlet ports which allow process gas to flow from the interior to the exterior of the container. Mounted on a first end of the counter electrode is a gas nozzle. In some embodiments, the gas nozzle has an inside diameter larger than an outside diameter of the counter electrode thus allowing a portion of the counter electrode to fit inside of the gas nozzle. In other embodiments the gas nozzle can be equivalent in diameter to the counter electrode. In another embodiment especially suited to coating multiple containers simultaneously, more than one counter electrode/gas inlet device can be located across the faceplate, each with its own corresponding location for mounting containers via mandrels within the chamber. Alternatively, the mandrel may be replaced with a common baffle plate that provides for counter electrode and gas inlet service through the plate while also allowing process gas to flow from the interior to exterior of the container either via gas outlet ports or by non-sealing contact between the plate and the containers top rim.

In accordance with the present invention, a method for depositing a coating on the interior surface of a container is also presented. The method includes mounting the container in the chamber and then evacuating the chamber. A first process gas is introduced into the interior to the container. The gas inlet also serves as the counter electrode. The first process gas is then ionized by coupling AC power, typically RF power, to the main electrode adjacent the exterior surface of the chamber and to the gas inlet to pre-treat the interior surface of the container. In one embodiment, the first process gas is nitrogen. The first process gas is ionized for 1 to 300 seconds and typically for 5 to 15 seconds. After the interior surface of the container is pre-treated, a second process gas comprising a mixture which includes oxygen and organosiloxane vapor is introduced through the counter electrode/gas inlet device into the interior of the container. The second process gas is ionized by coupling AC power, typically RF power, to the main electrode adjacent the exterior surface of the chamber and to the gas inlet to deposit the coating on the interior surface of the container. The second process gas is ionized for 1 to 300 seconds and typically for 5 to 15 seconds. After depositing the coating onto the interior surface of the container using the second process gas, a third process gas is introduced through the counter electrode/gas inlet device into the interior of the container. In one embodiment, the third process gas is oxygen. The third process gas is ionized by coupling AC power, typically RF power, to the main electrode adjacent the exterior surface of the chamber and to the gas inlet to post-treat the interior surface of the container. The third process gas is ionized for 1 to 300 seconds and typically for 5 to 15 seconds. Optionally, to minimize deposition of plasma on the exterior surfaces of the container, a low mass, hi-ionization potential gas such as helium can be introduced external to the container during the process. After post-treating the interior surface of the container, the chamber is vented and the container is removed. The deposited coating provides an excellent gas permeation barrier and imparts stain-resistant properties to the interior surface of the container. Further, since the coating is deposited on the interior surface of the container, the coating is not subject to abrasion during shipment and handling of the container as compared to exterior surface of the container. Also, by forming the coating on the interior surface of the container, degradation of the product within the container from direct interactions between the product and the container is prevented. Further, the coating is uniformly deposited without the necessity of rotating the container. Since the barrier coating is typically 1000 angstroms or less, the barrier coating represents a very small fraction of the material of the container, thus allowing the container to be readily recycled. The cycle time, typically of 5 to 30 seconds, is well suited for mass production of barrier coated containers. In addition, the apparatus is simple to operate, is relatively inexpensive to manufacture and needs little servicing.

The container covers and bases can be economically constructed from relatively thin-gauge plastic so that the user can either wash them after use or dispose of them with the view that their purchase price allows them to be used as a consumable good. The container can be readily manufactured, for example, with conventional thermoforming equipment. The cover can be made from a semi-transparent material to ensure satisfactory visibility of the container's contents. The container can be suitable for refrigerator, freezer, microwave, and machine dishwasher use. The container covers and bases are suitably stackable and engageable.

These and other objects, features and advantages of the present invention will be more readily apparent from the detailed description of the preferred embodiments set forth below taken in conjunction with the accompanying drawings.

### BRIEF DESCRIPTION OF THE DRAWINGS

FIG. 1 is a cross-sectional view of a container interior surface coating (CISC) reactor system having a container mounted inside of a cylindrical chamber in accordance with the prior art and one embodiment of the present invention.

FIG. 2 is an enlarged cross-sectional view of a gas inlet, a mandrel and the container of FIG. 1.

FIG. 3 is a frontal view of the chamber of FIG. 1 with the door and the container removed.

FIG. 4 is a cross-sectional view of a schematic representation of a container interior surface coating (CISC) reactor system having multiple containers mounted inside of a chamber according to an embodiment of the present invention featuring a planar main electrode.

FIG. 5 is a cross-sectional view of a schematic representation of a container interior surface coating (CISC) reactor system having multiple containers mounted inside of a chamber according to an embodiment of the present invention featuring a contoured main electrode.

FIG. 6A is a cross-sectional view of a counter electrode assembly comprising a tubular gas inlet and gas nozzle.

FIG. 6B is a side view of a counter electrode assembly comprising a tubular gas inlet and gas nozzle with side discharge ports resembling holes and slits.

FIG. 7 is a top view of a schematic representation of the chamber of FIG. 4

FIG. 8 is a top view of the chamber of FIG. 4 with the faceplate and containers removed.

FIG. 9 is a top hidden line view of the coating station showing engineering detail including the faceplate, faceplate guide shafts, faceplate reciprocating piston, chamber, and main electrode assembly, and the chamber guide assembly.

FIG. 10 is a cross-sectional hidden line view of the coating station of FIG. 9 showing engineering detail including the faceplate, faceplate corner guide shafts, chamber, chamber guide assembly, main electrode assembly, and coating station frame members.

FIG. 11 is a cross-sectional hidden line view of the coating station of FIG. 9 showing engineering detail including the faceplate, faceplate reciprocating pistons, chamber, chamber guide assembly, main electrode assembly, and coating station frame members.

FIG. 12 is a cross-sectional enlargement of the main electrode assembly of FIG. 10 and FIG. 11 showing engineering detail including the main electrode, main electrode embedding slabs, cap plate, base plate, and coating station frame members.

FIG. 13 is an embodiment of the coating apparatus.

FIG. 14 is an embodiment of the apparatus to measure container transparency.

### DETAILED DESCRIPTION OF THE INVENTION

In accordance with the present invention, a method and apparatus for plasma enhanced chemical vapor deposition of a thin film onto a surface of a container in presented.

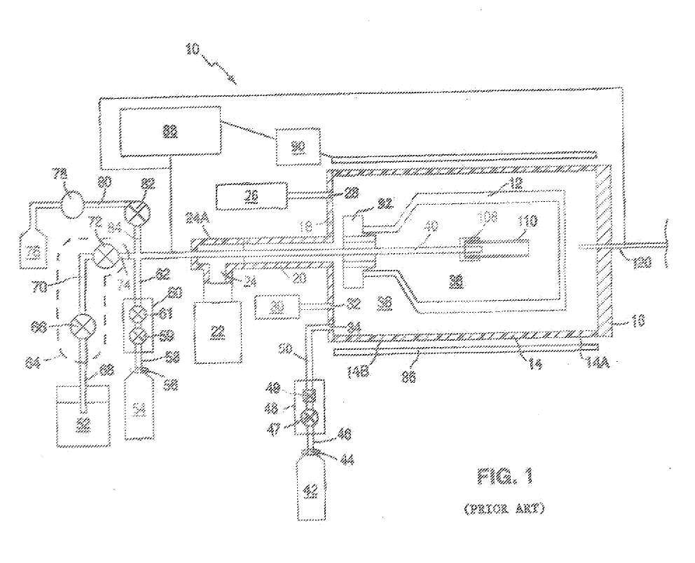

FIG. 1 is a cross-sectional view of a container interior surface coating (CISC) reactor system 10 having a container 12 mounted inside of a cylindrical chamber 14 in accordance with one embodiment of the present invention. Chamber 14 is made of an insulating material such as quartz although other insulating materials such as alumina or plastic can be used.

In this embodiment, the length of chamber 14, i.e. the distance from a first end 14A to a second end 14B of chamber 14, is 8.7 inches (in.) and the inside diameter of chamber 14 is 7.75 in. Generally, the inside diameter of chamber 14 is larger than the largest outside diameter of container 12. Preferably, the inside diameter of chamber 14 is at least 30% larger than the largest outside diameter of container 12. Chamber 14 is fitted on first end 14A with a door 16 which can be opened and closed to allow access to the interior of chamber 14. When door 16 is closed, i.e. when door 16 is in contact with end 14A as shown in FIG. 1, a vacuum seal is formed between door 16 and second end 14A using conventional means such as by locating an O-ring between door 16 and end 14A. A second end 14B of chamber 14 is vacuum sealed with a face plate 18 also using conventional techniques.

A pumping plenum 20 is concentrically attached on a first end to face plate 18. Pumping plenum 20 is also attached on a second end to a vacuum pump 22 by a T-coupler 24. In this embodiment, vacuum pump 22 is a conventional single or 2-stage rotary type mechanical pump which is set up for oxygen service. (Oxygen service typically requires the use of a fluorinated vacuum pump oil.) T-coupler 24 is made of an electrically insulating material such as teflon or another polymeric material although other electrically insulating materials such as ceramic can be used. T-coupler 24 is a Cole Parmer (Niles, Ill.) part #H-06482-88 Teflon PFA NPT (F) tee or a MDC Vacuum Product, Inc. (Hayward, Calif.) part #728007 PVC Tee with KF50 flanges (part #728007) for nominal 1.5 in. PVC pipe. During use, vacuum pump 22 removes gas from the inside of chamber 14 via pumping plenum 20 and T-coupler 24 thereby reducing the pressure within chamber 14 to a subatmospheric pressure. The pressure within chamber 14 is measured by a pressure transducer 26 which is exposed to the interior of chamber 14 at a pressure port 28 of face plate 18. Alternatively, a capacitance manometer or a thermocouple gauge can be used in place of pressure transducer 26. A vent valve 30 is also exposed to the interior of chamber 14 at a vent port 32 of face plate 18. When chamber 14 is at a subatmospheric pressure, vent valve 30 can be opened allowing air to be drawn into chamber 14 through vacuum port 32 thereby bringing the pressure within chamber 14 up to atmospheric pressure. Vent valve 30 can be plumbed (not shown) to an inert gas such as nitrogen thus allowing chamber 14 to be vented with an inert gas. Process gases can be fed into chamber 14 in at least two locations. In particular, a first process gas is introduced into chamber 14 in a region 36 exterior to container 12 through a gas inlet port 34 of face plate 18. A second process gas is introduced into chamber 14 in a region 38 interior to container 12 through a gas inlet 40. The first process gas is provided to region 36 from a first process gas source 42 which is typically a standard compressed gas cylinder. Generally, the first process gas has a low mass and a very high ionization potential. In this embodiment the first process gas is helium, although other gases such as hydrogen (H.sub.2), argon (Ar), Neon (Ne) or Krypton (Kr) can be used. Source 42 is coupled to gas inlet port 34 via a pressure regulator 44, a gas line 46, a gas flowmeter 48 and a gas line 50.

During use, regulator 44 reduces the pressure of the first process gas (which is at a relatively high pressure inside of source 42) and delivers the first process gas at a reduced pressure to gas line 46. The first process gas flows from regulator 44 through gas line 46 to gas flowmeter 48. Gas flowmeter 48 functions to control the on/off flow of the first process gas and also functions to control the volumetric flow rate of the first process gas to chamber 14. In this embodiment, gas flowmeter 48 includes a conventional shutoff valve 47 (such as a ball valve) which is the on/off control for the first process gas and a conventional metering valve 49 (such as a needle valve) which controls the flowrate of the first process gas. During use, shutoff valve 47 is opened thereby allowing the first process gas to flow to metering valve 49. Metering valve 49 is adjusted manually to increase or decrease an internal orifice of metering valve 49 thereby to increase or decrease, respectively, the volumetric flow rate of the first process gas. From flowmeter 48 (metering valve 49), the first process gas flows through gas line 50 to gas inlet port 34 and into region 36.

In this embodiment, the second process gas is a gas mixture having a first gas component provided from source 54 and a second gas component provided from source 52. Source 52 is a container of organosilicon liquid. Suitable organosilicon liquids include siloxanes such as hexamethyldisiloxane (HMDSO), 1,1,3,3-tetramethyldisiloxane (TMDSO), and octamethylcyclotetrasiloxane; alkoxysilanes such as amyltriethoxysilane, ethyltriethoxysilane, isobutyltriethoxysilane, and tetramethoxysilane; silazanes such as hexamethyldisilazane; and fluorine-containing silanes such as trimethylluorosilane. The container of source 52 preferably has a cover to prevent contaminants from falling into the reservoir of organosilicon liquid. However, to allow the organosilicon liquid to be removed from source 52 by liquid line 68, air (or another gas such as nitrogen) must be allowed to enter source 52 as the organosilicon liquid is removed. Source 54 is typically a standard compressed gas cylinder. As shown in FIG. 1, source 54 is coupled to gas inlet 40 via a pressure regulator 56, a gas line 58, a gas flowmeter 60 and a gas line 62. Since source 54 is generally a reactive gas, and typically an oxidizing gas such as oxygen, pressure regulator 56, gas line 58, gas flowmeter 60 and gas line 62 are manufactured to service oxidizing gases as those skilled in the art will understand. During use, regulator 56 reduces the pressure of the first gas component (which is at a relatively high pressure inside of source 54) and delivers the first gas component at a reduced pressure to gas line 58. The first gas component flows from regulator 56 through gas line 58 to gas flowmeter 60. In this embodiment, gas flowmeter 60 is substantially identical to gas flowmeter 48 and functions in a similar manner to control the on/off and volumetric flow of the first gas component to gas inlet 40. In particular, gas flowmeter 60 includes a shutoff valve 59 and a metering valve 61. From flowmeter 60 (metering valve 61), the first process gas flows through gas line 62 to gas inlet 40. The second gas component is provided to gas inlet 40 from source 52 via a vaporizer/flowcontroller system 64, hereinafter referred to as VF system 64. VF system 64 includes a liquid shutoff valve 66, a metering valve 72 and a capillary tube 70 coupled on a first end to valve 66 and on a second end to valve 72. As shown in FIG. 1, shutoff valve 66 is coupled to the liquid line 68 which extends into the reservoir of organosilicon liquid in source 52. Metering valve 72 is coupled to gas inlet 40 by a gas line 74. Capillary tube 70 has a typical inside diameter in the range of 0.001 in. to 0.010 in. and a typical length in the range of 0.25 in. to 2.0 in.

Although the present invention is not limited by any theory of operation, it is believed that VF system 64 operates as follows. When CISC reactor system 10 is initially setup, capillary tube 70 and liquid line 68 contain air and are at atmospheric pressure. Liquid line 68 is then inserted into the organosilicon liquid reservoir in source 52. As described in more detail below, chamber 14 is then evacuated by vacuum pump 22 which creates a vacuum in gas inlet 40. Metering valve 72 is then opened slightly, creating a corresponding vacuum in capillary tube 70. Shutoff valve 66 is then opened to draw the organosilicon liquid from source 52 through liquid line 68 into capillary tube 70. The inner diameter and length of liquid line 68 are selected such that, after organosilicon liquid is drawn into capillary tube 70, no air remains in liquid line 68, i.e. that liquid line 68 is filled with purely organosilicon liquid. Preferably, the inner diameter and length of liquid line 68 are less than or equal to 0.125 in. and 3.0 feet, respectively. In one embodiment, the inner diameter and length of liquid line 68 are 1/32 in. (0.031 in.) and 2.0 feet, respectively. Metering valve 72 is then shut and then liquid shutoff valve 66 is shut. At this point, liquid line 68 and capillary tube 70 are filled with purely organosilicon liquid (no air). In particular, capillary tube 70 holds a predetermined amount of organosilicon liquid which is determined by the length and inside diameter of capillary tube 70.

As described in more detail below, during processing of container 12, a vacuum is created in gas inlet 40. Metering valve 72 is then opened thereby drawing some of the organosilicon liquid out of capillary tube 70 into the subatmospheric pressure region of gas inlet 40. As the organosilicon liquid is exposed to the subatmospheric pressure, the organosilicon liquid boils thus producing organosilicon vapor. This continues until all of the organosilicon liquid in capillary tube 70 has been converted into organosilicon vapor. Since the amount of organosilicon vapor produced directly depends upon the amount of organosilicon liquid initially present in capillary tube 70 (which is predetermined), a fixed amount of organosilicon vapor is delivered from capillary tube 70. The flow rate at which the organosilicon vapor is delivered is controlled by adjusting metering valve 72. After the organosilicon liquid in capillary tube 70 is exhausted, metering valve 72 is closed thus leaving a vacuum in capillary tube 70. Liquid shutoff valve 66 is then opened which draws organosilicon liquid from liquid line 68 and source 52 into capillary tube 70, thus refilling capillary tube 70 with the predetermined amount of organosilicon liquid. Liquid shutoff valve 66 is then closed and VF system 64 is ready to deliver another fixed amount of organosilicon vapor to gas inlet 40.

In the above description, valves 49, 61 and 72 are described as metering valves. However, in an alternative embodiment, valves 49 and 61 are replaced with fixed orifices which are sized to provide the predetermined flow of the first process gas and the first gas component, respectively. Also, valve 72 is replaced with a shutoff valve which has a fixed orifice (or in combination with a fixed orifice) which is sized to provide the predetermined flow of the second gas component. Alternatively, flowmeters 48 and 60 can be replaced with electronic mass flow controllers. Further, VF system 64 can be replaced with a conventional vaporizer system. Also connected to gas inlet 40 is a pressurized gas source 76 such as a tank of compressed air. The pressurized gas source 76 is coupled to gas inlet 40 via a pressure regulator 78, a gas line 80, an ejection shutoff valve 82 and gas line 84. During use, regulator 78 reduces the pressure of the compressed gas and delivers the compressed gas at a reduced pressure to gas line 80. By opening ejection shutoff valve 82, gas inlet 40 is flushed with the compressed gas.

A main electrode 86 is provided adjacent the exterior surface of chamber 14. Main electrode 86 can be fashioned in a variety of shapes. For example, main electrode 86 can be a continuous coil or can be a plurality of separate cylindrical sections. In this embodiment, main electrode 86 is made of copper and is in the shape of a continuous cylinder. To allow main electrode 86 to fit over chamber 14, the inside diameter of main electrode 86 is slightly larger then the outside diameter of chamber 14. Preferably, main electrode 86 fits tightly over chamber 14. In this manner, any gap between main electrode 86 and chamber 14 is minimized and the power coupling efficiency from main electrode 86 to process gas within chamber 14 is maximized. Main electrode 86 is powered by a conventional power supply 88. Power supply 88 is generally an alternating current (AC) power supply and preferably operates at 13.56 megahertz (MHz) output frequency (typically referred to as a radio frequency or RF power supply). To match the impedance of power supply 88 to the impedance of the process, a matching network 90 is coupled between power supply 88 and main electrode 86. In this embodiment, the output impedance of power supply 88 is 50 ohms and matching network 90 is a conventional LC type matching network. For example, power supply 88 is a 250 watt, 13.56 MHz generator available from RF Plasma Products and matching network 90 is the corresponding matching network also available from RF Plasma Products. To complete the electrical circuit, power supply 88 is also electrically coupled to gas inlet 40 which, in addition to delivering the second process gas to region 38, operates as a counter electrode for power supply 88.

To allow gas inlet 40 to operate as a counter electrode, gas inlet 40 is made of an electrically conductive material. In this embodiment, gas inlet 40 is a hollow stainless steel tube which has an outside diameter of 0.125 in. Gas inlet 40 extends into chamber 14, and in particular extends through T-coupler 24 and pumping plenum 20, and into region 38. An air to vacuum seal is formed, for example by an O-ring, between T-coupler 24 and gas inlet 40 at a first end 24A of T-coupler 24. Since T-coupler 24 is made of an electrically insulating material, gas inlet 40 is electrically isolated from chamber 14, pumping plenum 20, face plate 18 and the associated components. Further, gas lines 62, 74 and 84 are typically formed from an electrically insulating material such as plastic thus electrically isolating gas inlet 40 from sources 52, 54, 76 and the associated gas delivery systems. However, it is understood that other configurations can be used to electrically isolate gas inlet 40 from sources 52, 54 and 76. As an illustration, gas line 74 can be steel and gas line 68 can be plastic. Gas inlet 40 is also electrically isolated from container 12 by a mandrel 92 formed of an electrically insulating material. Alternatively, mandrel 92 can be made of an electrically conductive material, although in this case container 12 would have to be made of an electrically insulating material.

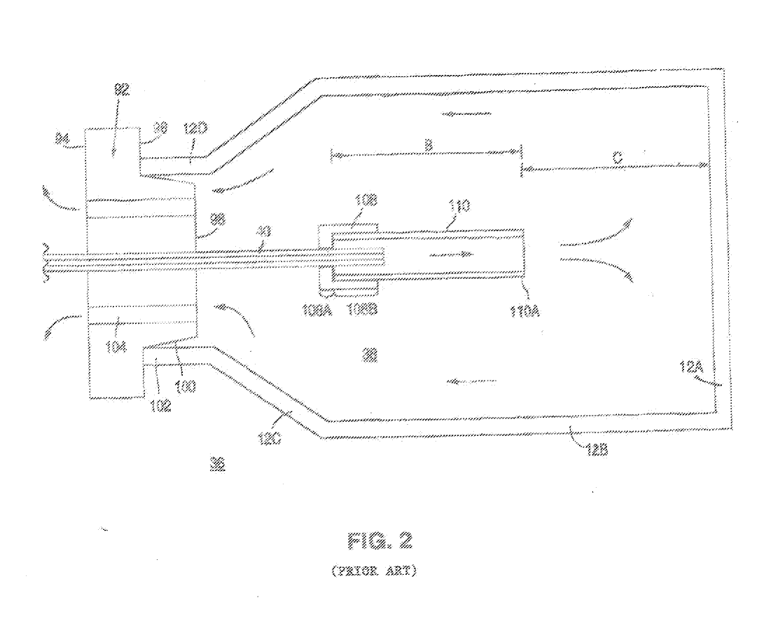

Referring now to FIG. 2, an enlarged cross-sectional view of gas inlet 40, mandrel 92 and container 12 are illustrated. As best seen in FIG. 2, gas inlet 40 extends concentrically through mandrel 92, i.e. extends through the middle of mandrel 92. The diameter of the central aperture through mandrel 92 through which gas inlet 40 extends is slightly larger than the outside diameter of gas inlet 40 to provide a friction fit between mandrel 92 and gas inlet 40. Through this friction fit, mandrel 92 is held in place inside of chamber 14. Mandrel 92 has a first surface 94 and a second surface 96 opposite first surface 94. A third surface 98 is raised from surface 96 to define a container mounting lip 100. Lip 100 has a taper to allow a friction fit between lip 100 and mouth 102. In particular, lip 100 has a first diameter at surface 98 slightly less than the inside diameter of mouth 102 of container 12 and a second diameter at surface 96 slightly greater than or equal to the inside diameter of mouth 102. Through this friction fit, container 12 is mounted to mandrel 92. Preferably, container 12 is mounted on mandrel 92 such that the edge of mouth 102 contacts surface 96 as shown in FIG. 2.

Extending through mandrel 92 from surface 98 to surface 94 are one or more gas outlet ports 104. In one embodiment, mandrel 92 has eight gas outlet ports 104 each having a diameter of 0.25 in. In general, the number and diameter of gas outlet ports 104 should be sufficient to prevent the differential in pressure between region 38 and region 36 from causing container 12 to be dismounted from mandrel 92 during processing of container 12. Preferably, gas outlet ports 104 are spaced evenly apart to ensure uniform gas flow. As shown in FIG. 2, a gas nozzle 110 is connected to an end of gas inlet 40 by a gas nozzle connector 108. Gas nozzle 110 is cylindrical and can be a piece of metal tubing or other electrically conductive material. In this embodiment, gas nozzle 110 has an inside diameter larger than the outside diameter of gas inlet 40 to allow gas inlet 40 to extend into gas nozzle 110 as shown in FIG. 2. In this embodiment, the inside diameter of gas nozzle 110 is 3/16 in. (0.188 in.) and the outside diameter of gas inlet 40 is ⅛ in. (0.125 in.). Gas nozzle connector 108 is cylindrical and has a first section 108A with an inside diameter slightly larger than the outside diameter of gas inlet 40 and a second section 108B with an inside diameter slightly larger than the outside diameter of gas nozzle 110. In this manner, friction fits are provided between gas inlet 40 and section 108A and between gas nozzle 110 and section 108B. Through these friction fits, gas nozzle 110 is mounted to gas inlet 40. Gas nozzle connector 108 is typically made of an electrically conductive material to form an electrical connection between gas inlet 40 and gas nozzle 110. In this embodiment, gas nozzle connector 108 is made of aluminum or stainless steel. The length B of gas nozzle 110 is generally between 2.0 in. and 6.0 in., but it can have other dimensions depending upon the particular dimensions of container 12. In general, the distance C between the end 110A of gas nozzle 110 and the bottom 12A of container 12 should be between 1.0 in. and 3.0 in. to ensure that reactive gases exiting from gas nozzle 110 reach all interior surfaces of container 12.

The arrows in FIG. 2 represent the forward flow of the second process gas during processing of container 12. In particular, the second process gas flows from gas inlet 40 through gas nozzle 110 and into region 38 proximate bottom 12A of container 12. The second process gas then flows along the length of container 12 to mandrel 92. The second process gas then flows from region 38 to region 36 through gas outlet ports 104 of mandrel 92. From region 36, gas is removed by vacuum pump 22 via pumping plenum 20 and T-coupler 24. In this embodiment, mouth 102 of container 12 has an inside diameter of approximately 1.4 in. which fits snugly (friction fits) over lip 100 of mandrel 92. Of importance, containers with other diameter mouths can readily be processed by CISC reactor system 10. As best seen in FIG. 2, gas nozzle 110 can quickly and easily be dismounted from gas inlet 40 simply by sliding gas nozzle coupler 108 off of gas inlet 40. Next, mandrel 92 is readily dismounted from gas inlet 40 by simply sliding mandrel 92 off of gas inlet 40. This allows another mandrel having a lip corresponding in size to the new container to be slid on to gas inlet 40. Gas nozzle coupler 108 with gas nozzle 110 is then slid back on to gas inlet 40. Alternatively, another gas nozzle having a different length B could be fit into gas nozzle coupler 108, for example to accommodate a longer or shorter container.

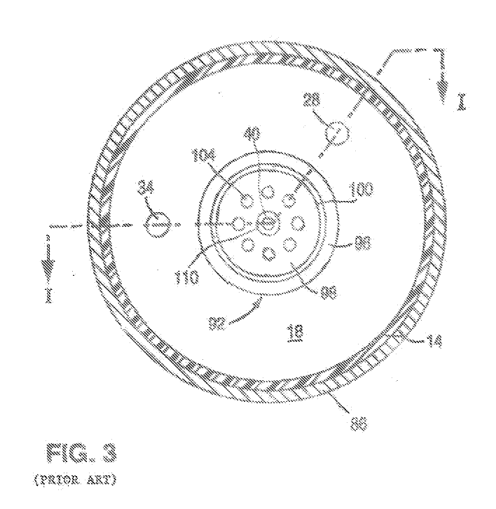

FIG. 3 is a frontal view of chamber 14 with door 16 and container 12 removed. The cross-sectional view of FIG. 1 is taken along the line I-I of FIG. 3. As shown in FIG. 3, mandrel 92, gas inlet 40 with gas nozzle 110 are located concentrically within chamber 14. Accordingly, by mounting container 12 on mandrel 92, container 12 is also located concentrically within chamber 14. The concentric geometry of CISC reactor system 10 ensures uniform power coupling and uniform gas flow thus enhancing the uniformity of the deposited thin film. In accordance with the present invention, a method of coating the container 12, typically a polymeric container is presented. Referring back to FIG. 1, initially, chamber 14 is at atmospheric pressure and there is no container in chamber 14. Door 16 is then opened and a container 12 is mounted onto mandrel 92. Container 12 is mounted on to mandrel 92 by hand. Alternatively, chamber 14 can be oriented vertically (as opposed to horizontally as in FIG. 1) with door 16 up and container 12 can be dropped on to mandrel 92 (gravity mounted). Door 16 is then shut. Mechanical pump 22 is then turned on to pump down chamber 14 to a subatmospheric pressure typically in the range of 0.050 torr to 1.000 torr and preferable to 0.100 torr. This subatmospheric pressure is measured by pressure transducer 26. Of importance, since chamber 14 is sized to have only a slightly larger volume than container 12, i.e. since chamber 14 has a minimum volume to be evacuated, mechanical pump 22 rapidly reduces the pressure in chamber 14 thus improving cycle time. The first and second process gases are then introduced into chamber 14 by opening shutoff valves 47, 59 and metering valve 72. Preferably, the first and second process gases are introduced into chamber 14 when the pressure in chamber 14 reaches 0.100 torr. The first process gas flowrate is set to between 1 standard cubic centimeter per minute (SCCM) and 1000 SCCM and preferably is set to 400 SCCM. In particular, the first process gas flowrate is set such that the chamber pressure in region 36 is within the range of 0.050 torr to 10.000 torr, preferably 0.500 torr. As discussed above, the first process gas flowrate is controlled by adjustment of metering valve 49. The second process gas flowrate is equal to the flowrates of the first and second gas components. The first gas component flowrate is generally set to between 10 SCCM to 1000 SCCM and preferably is set to 200 SCCM. As discussed above, the first gas component flowrate is controlled by adjustment of metering valve 61. The second gas component flowrate is generally set to between 1 SCCM to 100 SCCM and preferably is set to 20 SCCM. As discussed above, the second gas component flowrate is controlled by adjustment of metering valve 72. Generally, the ratio of the flow rates of the second gas component to the first gas component is between 1:1 and 1:100 and preferably is 1:10. After the first and second process gas flows have stabilized (approximately 1.0 second), power supply 88 is turned on and AC power is coupled to main electrode 86 and gas inlet 40. This ionizes the gases in regions 36 and 38. If necessary, matching network 90 is adjusted to match the impedance of the power supply 88 to the impedance of the resultant process plasmas. The process power is set to between 0.1 and 5.0 watts per cubic centimeter (cc) of region 38, i.e. per the volume of container 12 in cubic centimeters. Preferably, for a 0.5 liter bottle, the process power is set to 0.25 watts/cc. In this embodiment, the first process gas is helium, the first gas component of the second process gas is oxygen and the second gas component of the second process gas is hexamethlydisiloxane (HMDSO).

Although the present invention is not limited by any theory of operation, it is believed that the plasma generated in region 38 decomposes the HMDSO vapor breaking off the methyl groups. The oxygen oxidizes the methyl groups and any other organic groups formed thus enhancing the volatilization and gas phase removal to pump 22 of these groups. Further, the oxygen oxidizes the condensible siloxane backbone (Si—O—Si) resulting from the HMDSO decomposition to form a plasma enhanced chemical vapor deposition (PECVD) thin film of silicon oxide (SiO.sub.x) on the interior surface of container 12, i.e. on the surface of container 12 in contact with region 38. Further, since the surface area of powered gas inlet 40 with gas nozzle 110 is much less than the surface area of main electrode 86, the voltage on gas inlet 40 and gas nozzle 110 will be relatively high. This high voltage causes significant ion bombardment of gas inlet 40 and gas nozzle 110, thus essentially eliminating any coating deposition on gas inlet 40 or gas nozzle 110. This advantageously increases the number of containers which can be coated before CISC reactor system 10 must be serviced. Further, the significant ion bombardment causes gas inlet 40 and gas nozzle 110 to become heated. This heats the interior surface of container 12 which densifies the deposited coating and enhances the barrier properties of the deposited coating. Further, the high voltage on gas inlet 40 and gas nozzle 110 causes both the first and second gas components of the second process gas to be ionized simultaneously inside of gas nozzle 110 before being discharged to and further ionized in region 38 outside of gas nozzle 110. This causes the second process gas to be highly activated (to have a high degree of ionization) throughout region 38 thus enhancing the uniformity of the coating deposited on the interior surface of container 12. After a predetermined amount of time, generally 1 to 300 seconds and typically 5 to 15 seconds, power supply 88, the first and second process gas flows and mechanical pump 22 are shut off. To shut off the first and second process gases, shutoff valves 47, 59 and metering valve 72 are closed. It is understood that the organosilicon liquid in capillary tube 70 may be completely vaporized before metering valve 72 is closed and thus the flow of the organosilicon vapor may have ceased before metering valve 72 is closed. Chamber 14 is then vented to atmospheric pressure by opening vent valve 30. When chamber 14 reaches atmospheric pressure as measured by pressure transducer 26, door 16 is opened. Ejection shutoff valve 82 is then opened thus providing a blast of compressed gas through gas inlet 40. This blast of compressed gas ejects container 12 from mandrel 92. This blast of compressed gas also serves to remove any particulates from the interior of gas inlet 40 and gas nozzle 110 essentially eliminating any pinhole or other particulate defects of the barrier coating deposited on the interior surface of the succeeding container. At this point, a new container is loaded on to mandrel 92 and processed.

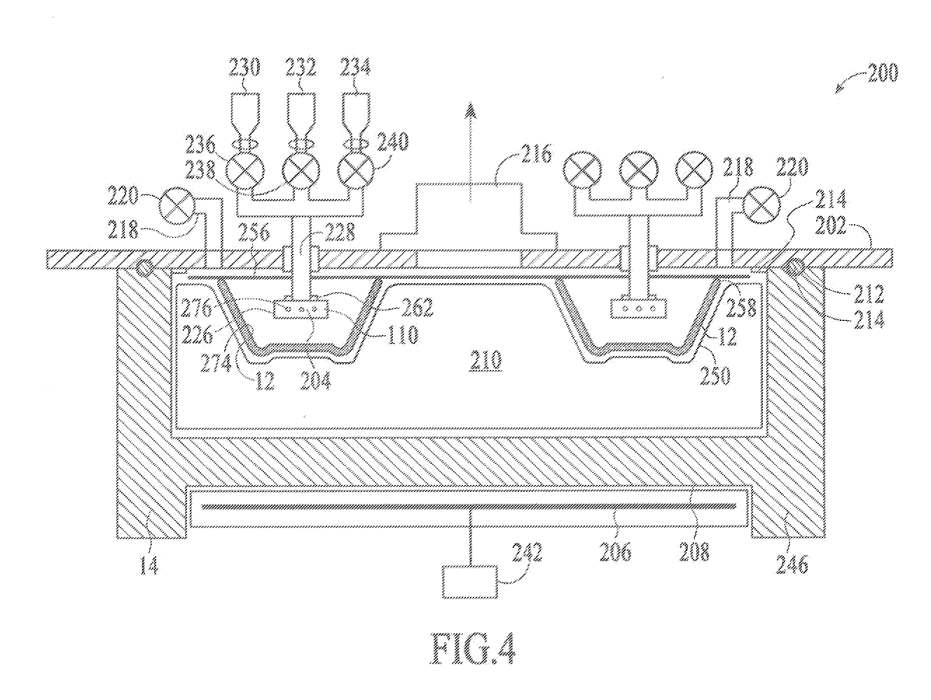

FIG. 4 is a cross-sectional view of a container interior surface coating (CISC) reactor system 200 having multiple containers 12 mounted inside of a chamber 14 according to an embodiment of the present invention. This embodiment can incorporate all features presented in the embodiment described in FIGS. 1-3 but differs in that the chamber 14 comprises a continuously sealed cavity made of an electrically insulating material sealed on one end by a lid assembly 202 capable of forming a vacuum seal, where the interior chamber dimensions will allow for placement of multiple containers 12. Additionally, the lid assembly 202 may include locations concentric with respect to the containers 12 for more than one counter electrode/gas inlet assembly 204, and the main electrode 206 is a planar radiating surface adjacent to the exterior of the entire chamber wall 208 opposite and parallel to the lid assembly 202. The chamber 14 is made of ultra high molecular weight high density polyethylene but can comprise other insulating materials such as quartz, alumina, or other polymeric materials. During chamber loading, the lid assembly 202 is re-positioned away from the chamber 14 permitting egress into the chamber 14. Containers 12 can be positioned within the chamber 14 by placing them into a non-conducting insert 210. The insert 210 serves to position containers 12 for coating and it occupies spatial volume external to the container to reduce headspace during chamber evacuation, thus decreasing cycle time. Furthermore, the insert 210 can be designed to accommodate containers 12 of varying size so that production of different container types can occur simply by changing the insert 210 to one designed for that specific container style and as such allow coating of multiple container types within a common CISC system 200. During processing, the lid assembly 202 abuts to the chamber 14 to create a vacuum seal and may include a groove 212 to mount an O-ring 214 or other conventional means to affect a vacuum seal. The lid assembly 202 can be either electrically conducting or non-conducting and the lid assembly material choice may be dictated by cost and structural strength considerations. A pumping plenum 216 is attached directly to the lid assembly 202. The lid assembly 202 includes vent ports 218 coupled to exhaust valves 220 for the purpose of venting the chamber 14 to atmosphere. The lid assembly 202 may also include a port to accommodate measurement using a pressure transducer, or the pressure transducer 214 may be mounted inside the chamber 14. The lid assembly 202 may also include locations for more than one counter electrode 226 such that the counter electrode 226 is not required to extend through the pumping plenum 216. When using a lid assembly 202 that is electrically conducting, each counter electrode 226 is electrically connected to the lid assembly 202 forming a grounding circuit. The lid assembly 202 also has at least one gas inlet port 228 that comprises a counter electrode 226 that is connected to a first process gas source 230, a second process gas source 232, and a third process gas source 234. A first flow controller 236 is coupled between the gas inlet port 228 and the first process gas source 230. The first flow controller 236 has the capability of controlling the flow of gas from the first process gas source 230 to the chamber 14. Connected to the counter electrode 226 is a second process gas source 232. The second process gas source 232 is a container of organosilicon liquid. A vaporizer/flow controller system (VF system) 238 is provided to vaporize the organosilicon liquid into organosilicon vapor and to control the flowrate of the organosilicon vapor generated. Also connected to the counter electrode 226 is a third process gas source 234. A third flow controller 240 is coupled between the gas inlet port 228 and the third process gas source 234. In other embodiments, capillary tubes with inside diameters ranging from 0.001″ to 0.010″ can be used interchangeably with flow meters (is this the same as flow controller?). Using this scheme, either the first 230, second 232 or third gas sources 234 can be introduced into the chamber 14 through the gas inlet 228, either alone or in combination.

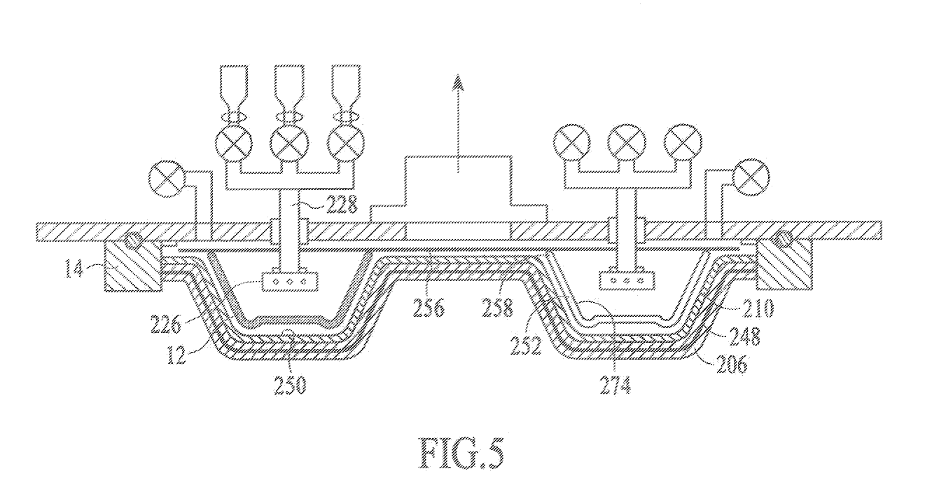

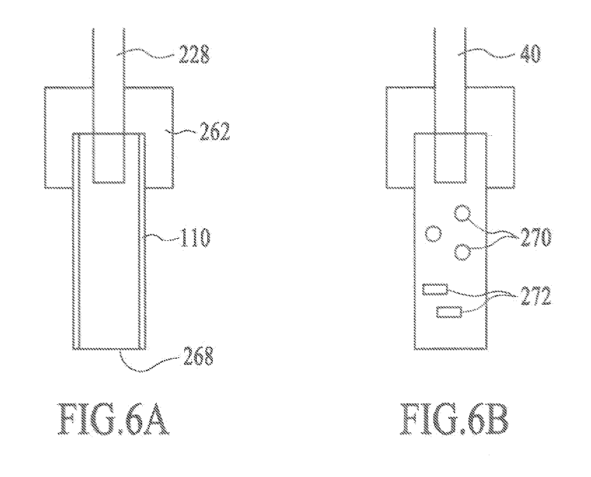

The main electrode 206 and counter electrodes 226 are powered by an alternating current (AC) power supply 242 which preferably has an output frequency of 13.56 megahertz (MHz). In this embodiment, the main electrode 206 is expediently configured as a planar radiating surface adjacent to the exterior of the entire chamber wall 208 opposite and parallel to the lid assembly 202. It is stationary and embedded in electrically insulating material. The embedded main electrode 206 is not integral with the chamber 14 as it is advantageous to allow horizontal shuttling of the chamber 14 into and out of the coating station 244 (FIG. 9), for instance to facilitate loading and unloading of containers 12. Generally the plane of this radiating surface is equidistant to each counter electrode 226. In other embodiments that may enhance deposition rates, the main electrode 206 can be configured in more complex non-planar shapes. For instance a portion of the main electrode 206 may extend about the sidewalls 246 of the chamber 14 while the remaining portion is configured as shown. In another embodiment as shown in FIG. 5, the bottom portion 248 of chamber 14 may resemble the upper surface 250 of the insert 210 which is designed to hold the containers 12 concentrically about the counter electrodes 226. In this case, the main electrode 206 may more closely follow the contour of each container 12 in the chamber 14 such that the radiating surface parallels the container wall 252, thereby decreasing the distance between the main electrode 206 and counter electrodes 226. In some embodiments, it may be advantageous to provide an embedded main electrode 206 that is capable of moving vertically into position before being powered. Thus it can be retracted, to a stand-by position so as to allow horizontal shuttling of the chamber 14 into and out of the coating station 244 (FIG. 9) to facilitate container handling. The counter electrodes 226/gas inlets 228 extend through a common, non-conducting baffle plate 256 that during processing resides in close proximity to the top rim 258 of the containers 12 loaded within the chamber 14. The baffle plate 256 provides for counter electrode 226 and gas inlet 228 service through the plate 256 while also allowing process gas to flow from the interior to exterior of the container 12 either via shielded vents in baffle plate 256 or via non-sealing contact between the plate 256 and the containers top rim 258. The baffle plate 256 can be made of an inexpensive material such as plastic and is sacrificial being that it may be coated during the plasma deposition step and require periodic replacement. As shown in FIGS. 4, 6A and 6B, gas nozzle 110 is connected to an end of each gas inlet 228 by a gas nozzle connector 262. The nozzle connector 262 is typically shaped to frictionally adapt a connection between both the gas inlet 228 and the nozzle 110. The gas nozzle 110 can be a piece of metal tubing or other electrically conductive material. Gas nozzle connector 262 is typically made of an electrically conductive material to form an electrical connection between gas inlet 228 and gas nozzle 110. In this embodiment, gas nozzle connector 262 is made of aluminum or stainless steel. The gas nozzle 110 can quickly and easily be dismounted from the gas inlet 228 simply by sliding the gas nozzle connector 262 off of the gas inlet 228, after which the baffle plate 256 can be slid off the gas inlets 228.

The gas nozzle 110 can be cylindrical or it can be non-circular with respect to its cross-section, its shape being optimized for the shape of the container 12. The gas nozzle 110 can also be either an open tube or have a plurality of holes (ranging in diameter from 0.01″ to 0.125″. The gas nozzle 110 when assembled may have a single discharge point 268 at the lower end of the nozzle 110 or it may contain circular side-ports 270 or side-slots 272 located at points along its length. In general, it may be advantageous to design the gas nozzle 110 such that the distance between the discharge point(s) and all points along the containers interior surface 274 are substantially equidistant to ensure that reactive gases exiting from gas nozzle 110 reach all interior surfaces 274 of container 12 for uniform coating. For cylindrical containers, it may be advantageous to employ a cylindrical gas nozzle 110 since the distance between the nozzle discharge point(s) 276 and all points along the containers interior surface 274 are substantially equidistant, thus ensuring that reactive gases exiting from gas nozzle 110 reach all interior surfaces 274 of container for uniform coating. For square or rectangular containers, it may be advantageous to employ a gas nozzle 110 with a square or rectangular shape with respect to its cross-section incorporating side-ports or side-slots directed at the containers corners, since reactive gas flowing from the discharge point(s) of the concentrically located nozzle would be more likely to reach the interior surfaces of the container at the more distant corners, thus imparting more uniform coating. Alternatively, it may be advantageous to purposefully increase coating thickness in certain areas along the inside surface of the container to enhance stain-resistant performance in those areas that are most often damaged. In this case, increasing deposition rates that result in increased coating thickness where most needed can shorten cycle time and reduce material usage. For instance, in the case of using a polypropylene container for microwave re-heating of tomato-based foods, it is typical that containers will exhibit noticeable orange-colored staining on the sidewall just below the meniscus and noticeable melt pitting generally scattered at and above the meniscus. In this case, melt pitting can be described as small white and orange-colored discontinuous areas of irregular shape and size, indicating that the normally translucent polymer surface was melted and etched by the highly heated food contents. When plasma depositing SiOx on the interior surface of a polypropylene container to impart stain-resistance, it may be beneficial to preferentially increase coating thickness about the fill line of the container sidewalls where the meniscus most often occurs since that is the area that is most deleteriously attacked during microwave re-heating. The employment of specific nozzle and electrode configurations that achieve this result may be advantageous. For instance the nozzle may be designed such that the flow rate of reactive gases exiting the nozzle and directed at the sidewalls about the fill line of the container could be greater than gaseous flow rates elsewhere about the container, thereby increasing deposition rates and coating thickness where most needed to shorten cycle time and reduce material usage.

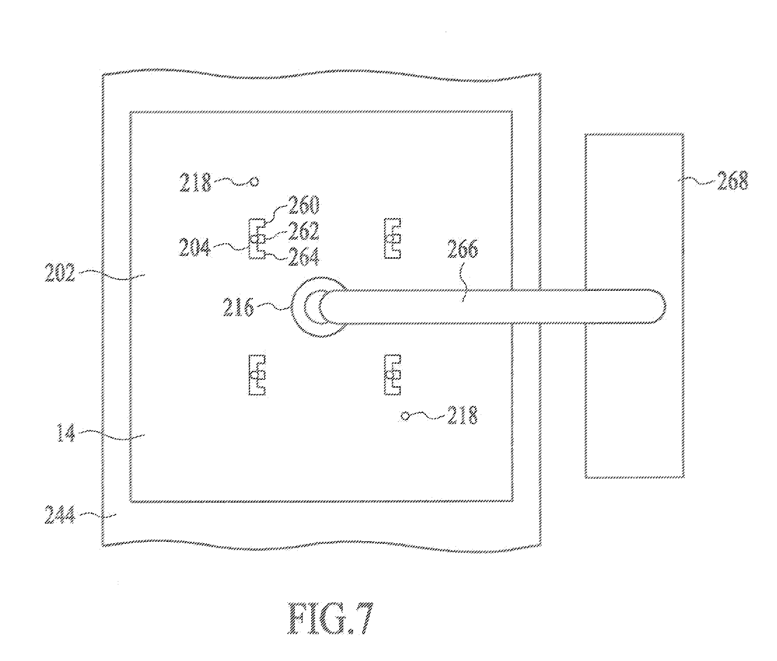

FIG. 7 is a top view of the chamber 14 of FIG. 4. This view schematically shows the multiple locations for counter electrode/gas inlet assemblies 204. Each assembly 204 comprises a counter electrode and provides for three gas sources 260, 262, 264 located concentrically with respect to the container within the chamber 14. This embodiment shows that four containers can be coated during one loading/cycle. This configuration is not intended to be limiting with regard to the number of containers that can be coated by this invention. Any number of counter electrode/gas inlet assemblies 204 can be envisioned as dictated by coat and production capacity requirements. In this embodiment, the lid assembly 202 includes one centrically located pumping plenum 216 having a flex hose 266 connecting to a pump 268 and two vent ports 218 located at opposite corners of the lid assembly 202. The invention described herein may include one or more plenums and vents that are located centrally or in other positions on the lid assembly.

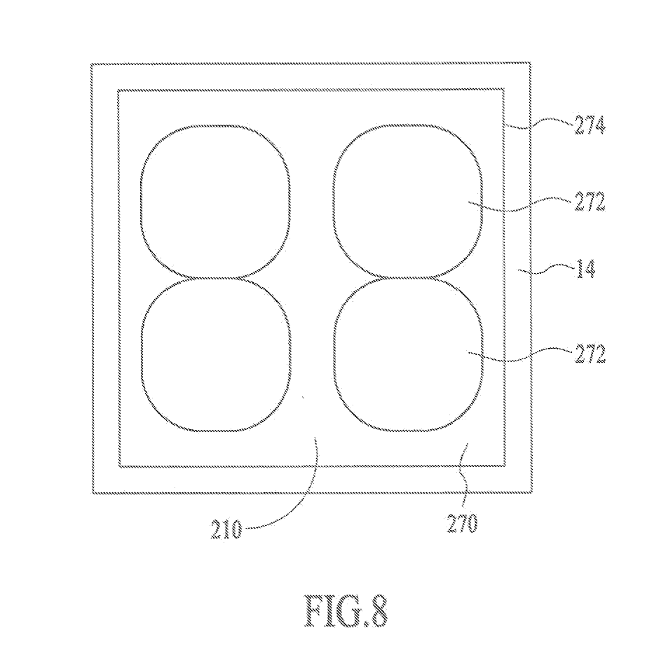

FIG. 8 is a top view of the chamber 14 of FIG. 4 with the lid assembly 202 and containers removed. This view schematically shows a top view of the interior of the chamber 14. This view shows the top side of the insert 210 within the chamber 14 comprising at least one solid body portion 270 that extends to all chamber walls 274 to fill headspace and multiple indent locations for insert locating wells 272. The wells 272 are typically formed to follow the outline of the container footprint and contoured to follow the shape of the sides and bottom of the container, thus serving to locate and align the container during loading and subsequently arresting lateral movement of the container during processing. Most importantly, the wells 272 function to concentrically locate the containers with respect to the electrodes extending through the lid assembly 202 as shown in FIGS. 4 and 7. This embodiment shows that four containers can be coated during one loading/cycle. This configuration is not intended to be limiting with regard to the number of containers that can be coated by this invention. Any number of insert locating wells can be envisioned as dictated by cost and production capacity requirements.

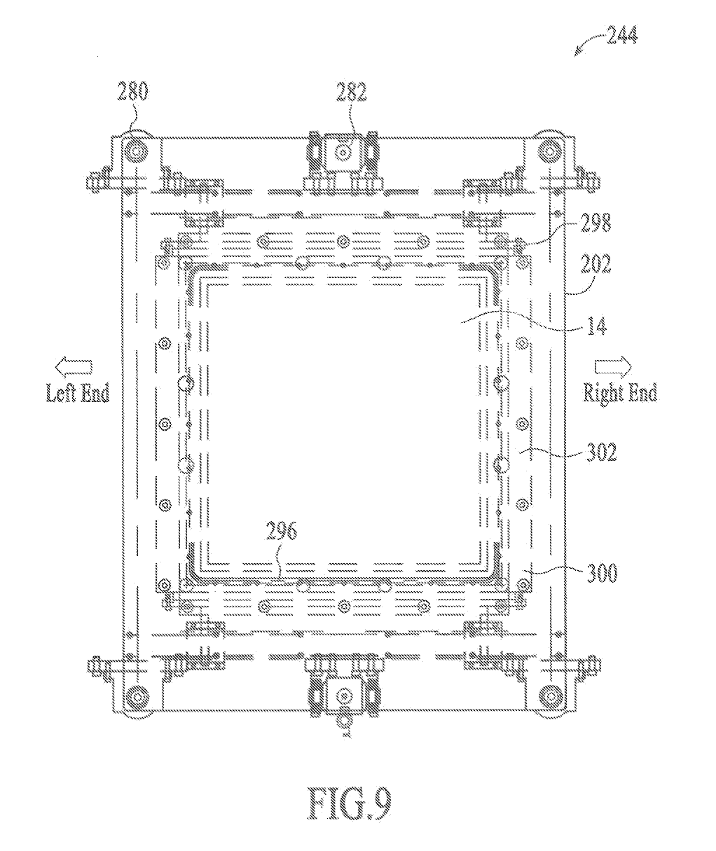

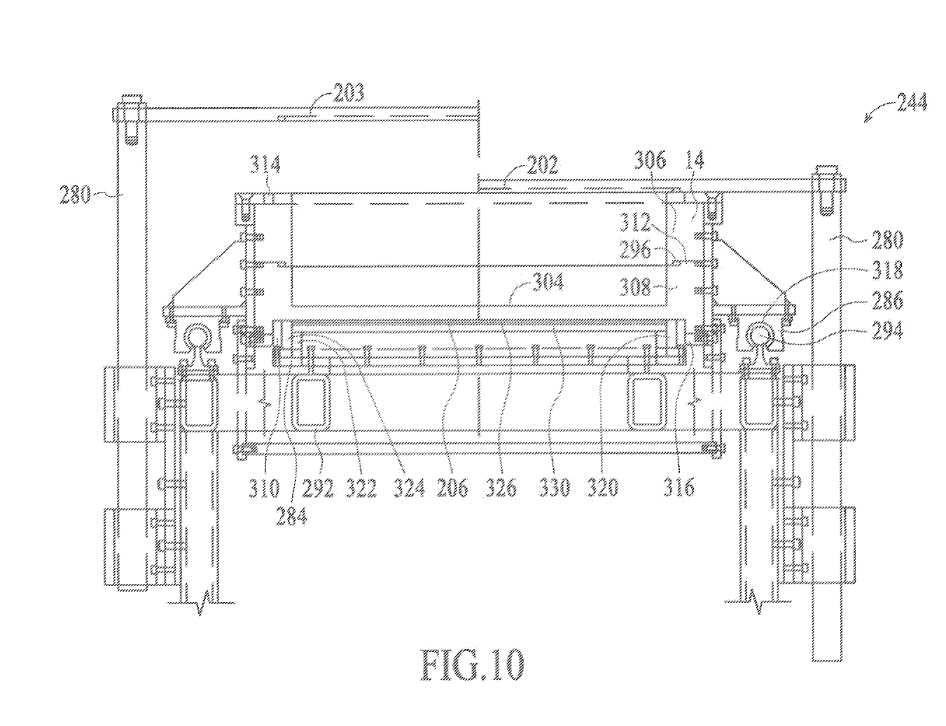

FIG. 9 is a top hidden line view of the coating station 244 showing engineering detail including the lid assembly 202, lid assembly guide shafts 280, lid assembly reciprocating piston 282, chamber 14. FIG. 10 is a cross-sectional hidden line view of the coating station 244 of FIG. 9 showing engineering detail including the lid assembly in the down position 202, lid assembly in the up position 203, lid assembly guide shafts 280, chamber 14, chamber guide assembly 286, main electrode assembly 284, and coating station frame members 292. FIG. 11 is a cross-sectional hidden line view of the coating station of FIG. 9 showing engineering detail including the lid assembly 202, lid assembly reciprocating pistons 282, chamber 14, chamber guide assembly 286, main electrode assembly 284, and coating station frame members 292. Not shown in FIGS. 9, 10, and 11 are certain lid assembly features including vents, plenums, and counter electrode/gas inlets. Also not shown in FIGS. 9, 10, and 11 is the chamber contents, including insert and containers. The movement of the chamber 14 proceeds along chamber guide shafts 294 and the directionality of the chamber movement into and out of the coating station 244 is indicated by the arrows (FIG. 9). The lid assembly 202 is guided in its vertical movement by guide shafts 280 located at each of the four corners (FIG. 9). The lid assembly 202 is driven by pneumatic cylinders located at the midline of the coating station 244 adjacent to the chamber guide shafts 294 (FIGS. 10, 11). As shown in FIGS. 10 and 11, this motion occurs such that the lid assembly 202 moves up to stand-by (203) and down (202) to the upper surface of the chamber 14 to initiate the coating process. Other conventional means can be employed to move the lid assembly 202 in its vertical path including toggle mechanisms, rotary cams, screw gears, etc.

FIG. 9 includes a top view of the chamber 14 located below the lid assembly 202 in hidden line view, including the chamber clamping frame assembly including side frame members 298 lying along the sides of the chamber 14 parallel to the direction of chamber movement and spanner frame members 300 lying along the sides of the chamber 14 perpendicular to the direction of chamber movement. Fastened to the side frames 298 and spanner frames 300 are upper clamp bars 302 located about the chamber perimeter. Also shown in FIG. 9 is the location for an O-Ring 296 to provide sealing means between the lid assembly 202 and chamber 14.

FIG. 10 includes a cross-sectional view of a chamber 14 comprising a continuous cavity 304 made of an electrically insulating material sealed on one end by a lid assembly 202 capable of forming a vacuum seal. The interior chamber dimensions will accommodate the exchangeable solid body insert and allow for placement of multiple containers. Additionally, this is an embodiment that offers cost advantages owing to the use of readily available commercial slabs of electrically insulating material that comprise the bottom and sides of the chamber. The slabs comprise thick sheet stock that can be machined to form specific features required for the chamber cavity. In this embodiment, there are two such slabs, an upper slab 306 that has been machined to provide a square-shaped upper side wall and a lower slab 308 that has been machined to provide a continuous cavity comprising the bottom of the chamber and protruding lower side wall. The lower slab 308 also features a bottom detent 310 that allows the main electrode assembly to be located immediately adjacent to the bottom of the chamber and in close proximity to the counter electrodes. Each slab section abuts to the next to create a vacuum seal using conventional means to affect a vacuum seal, for instance a groove 312 and O-ring 296. In this case, an O-ring groove 312 is located on the upper surface of the lower slab 308. The use of multiple slabs to construct the chamber is advantageous since it may be impractical or costly to use a single continuous block of material to achieve large chamber dimensions. Furthermore, it is impractical to connect multiple slabs of relatively soft durometer electrically insulating materials such as ultra high molecular weight high density polyethylene using conventional means of fastening, such as screws, owing to the likelihood that the material will locally deform in the area of the fastener given that the slabs need to be squeezed together with high force to ensure an airtight seal. In this case, an abutment of the slabs is accomplished by use of a special chamber clamping frame that uniformly squeezes the slab about the perimeter without resorting to the use of individual fasteners tapped into the soft chamber structure. The chamber clamping frame applies compressive force to each slab to squeeze the slabs together. On the upper slab 306, this force is applied at a rabbit 314 that extends about the upper perimeter of the upper slab 306; the rabbit 314 being deep enough such that the chamber clamping frame structure does not protrude above the upper surface of the slab 306 since doing so would interfere with the lid assembly 202 seating properly on the upper slab 306 during processing. The lower end of the chamber clamping frame applies compressive force about the lower perimeter at the face of the lower slab 308. The chamber clamping frame is manufactured using aluminum or steel and comprises an upper clamp bar 302 extending about the perimeter of the upper slab 306, a lower clamp bar 316 extending about the perimeter of the lower slab 308, and side frame members 298 and spanner frame members 300 that provide fastening means for the clamp bars 302, 316. The side frame members 298 and spanner frame members 300 are connected as an assembly by conventional fastening means, as shown in this case by screw fasteners that extend through the ends of the spanner frames 300 and thread into the side frames 298 where they abut at the corners of the assembly. In this embodiment, the side frame member 298 comprises welded plate stock and provides fastening holes for clamp bar 302, 316 mounting and lateral extensions for attaching pillow blocks 318 that ride along guide shafts 294 and guide the chamber 14 so as to allow horizontal shuttling of the chamber 14 into and out of the coating station 244. It is important that the chamber clamping frame be designed so as not to interfere with the RF field during the plasma coating process. Preferably the chamber clamping frame is bare unpainted aluminum or steel and electrically grounded.

Also shown in FIGS. 10 and 11 is a cross section of the main electrode 206, in this case a planar copper sheet of 1/16 inch thickness that is embedded between and an upper embedding slab 320 and lower embedding slab 322 of ultra high molecular weight high density polyethylene. The main electrode 206 is protectively embedded within electrically insulating material for purposes of structural integrity. Also portions of this assembly provide means for mounting the main electrode 206 to coating station framework. The upper embedding slab 320 is machined so as to provide side walls 324 with an outwardly extending perimeter flange and a protective wall member 326 on the top surface that comprises a 1/16 inch thick insulating cover portion. The cover portion thickness is minimal so as to allow the radiating surface to be in close proximity to the counter electrodes located with the chamber 14 to affect a proper RF field for the plasma coating process. The lower embedding slab 322 is machined to fit within the sidewalls 324 of the upper embedding slab 320 and provide structural support underneath the main electrode 206 to hold it in intimate contact with the protective wall member 326 of the upper embedding slab 320. The assembly can be fastened together using conventional means so long as these means do not interfere with the RF field during the plasma coating process. In this case, the fastening means are located proximally distant from the main electrode 206, this distance being equivalent to the height of the sidewall of the main electrode assembly 330, and comprise multiple screw fasteners about the perimeter of the assembly that extend through a cap plate 332, through the sidewalls 324 of the upper embedding slab 320, and thread into a base plate 328 whereby the base plate 328 retains the lower embedding slab 322. The base plate 328 of the main electrode assembly 330 provides for mounting to coating station frame members 292 using conventional means. It is important that the cap plate 332 and base plate 328 be designed so as not to interfere with the RF field during the plasma coating process. Preferably the cap plate 322 and base plate 328 comprise bare unpainted aluminum or steel and are electrically grounded to the coating station frame.

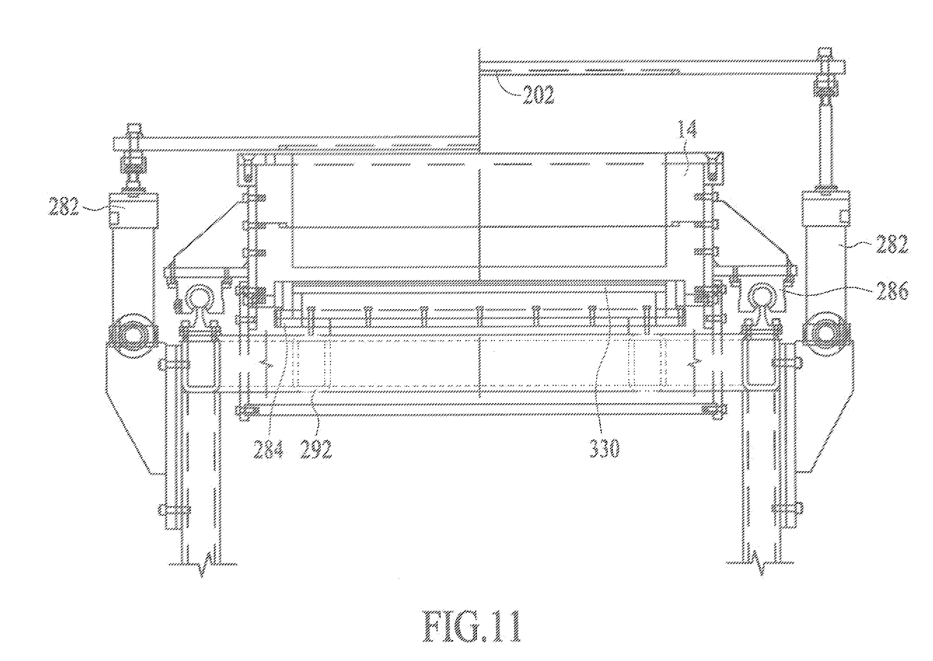

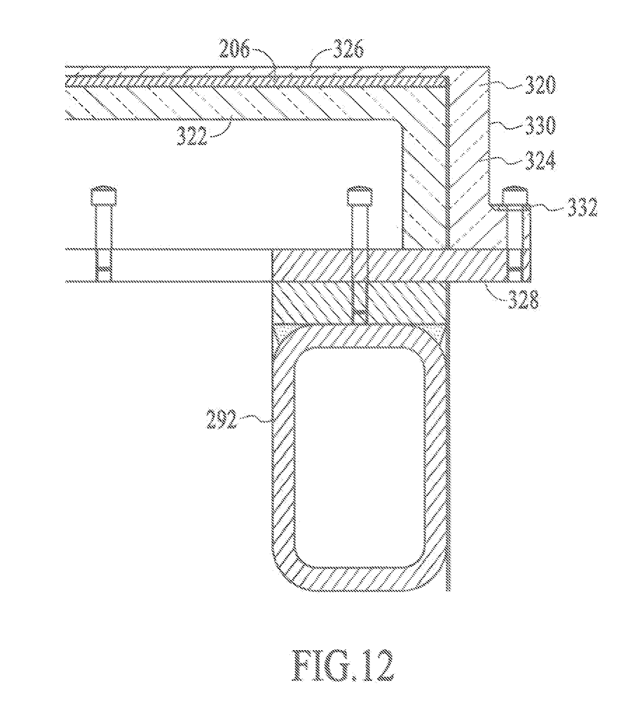

During processing, the main electrode assembly 330 shown in FIGS. 10, 11 and 12 is located immediately adjacent to the bottom of the chamber 14 with minimal air gap between the electrode assembly 330 and chamber 14. In this embodiment, the embedded main electrode 206 is stationary and not integral with the chamber 14 as it is advantageous to allow horizontal shuttling of the chamber 14 into and out of the coating station 244 to facilitate loading and unloading of containers. The main electrode assembly 330 is dimensioned to fit within the detent 310 of the chamber lower slab 308. It is important to point out that, in this embodiment where the chamber 14 moves horizontally into alignment with a stationary main electrode 206, the detent 310 located at the bottom of the chamber 14 is created by machining the lower slab 308 and chamber spanner frame members 300 such that no wall portions exist that would prevent the chamber 14 from moving into or out of the coating station 244 in the conveying direction. This invention is not limited to a single chamber. Any number of chambers can be conveyed into the coating station in series in order to meet production capacity requirements, and these chambers can proceed in a linear, non-linear, or rotational fashion along a circuit comprising guide shafts or other conveying means. The conveyance means can form a terminated circuit requiring reciprocating chamber movement to move the chambers into and out of the coating station, or on a continuous, closed loop circuit such that the chambers can proceed in a single direction and a given chamber moves into the coating station periodically. Furthermore, multiple coating stations can be positioned about the circuit if deemed appropriate given productivity requirements.

Container

The container can be made from any suitable plastic and can be made by any suitable technique, such as co-extrusion, lamination, injection molding, vacuum thermoforming, or overmolding. Vacuum thermoforming is typically the most economical means for forming the container. As is well know in the art, vacuum thermoforming involves heating a suitable plastic sheet of material to a temperature at which the sheet becomes formable into a shape that is set as the plastic sheet cools. As used herein, a suitable plastic sheet is a plastic sheet that may be readily used by the vacuum thermoforming process. The heated plastic sheet is made to conform to the surface features of a single surface “male” tool by drawing the heated sheet of plastic to the surface of the tool by the force of a vacuum applied to the tool. In vacuum thermoforming, the sealed air space between the heated plastic and mold is evacuated to draw the heated plastic to contact the single male surface of the mold. Injection molding of a plastic article involves heating suitable plastic material in the form of pellets or granules until a melt is obtained. The melt is next forced into a split-die mold, sometimes referred to as a split-die tool, where it is allowed to “cool” into the desired shape. Both the bottom surface and the top surface of the plastic article are formable by the split-die mold. Thus, articles may by formed by the injection molding process that have side cross-sectional profiles of varying non-uniform thickness. After the plastic melt cools, the split-die mold is opened and the article is ejected. Since, the mold is separable, undercut surface on the plastic article may be relieved from the split-die mold when it is opened. Injection molding, well know in the art, is typically used to form plastic articles that have large undercuts and substantially varying thicknesses in side cross-sectional profile. As used herein undercuts are said to be large if a molded plastic article having undercut features is difficult or impossible to remove from a single-surface vacuum thermoforming mold after it is formed and cooled.

The container can be fabricated by vacuum thermoforming a clarified polypropylene homopolymer material. In another embodiment, the container may be fabricated by vacuum thermoforming a clarified random copolymer polypropylene material. Other plastic materials which would be suitable for fabricating the container by vacuum thermoforming include PS (polystyrene), CPET (crystalline polyethylene terephthalate), APET (amorphous polyethylene terephthalate), HDPE (high density polyethylene), PVC (polyvinyl chloride), PC (polycarbonate), and foamed polypropylene. The material used can be generally transparent to allow a user to view the contents of the container. The container is more fully described in WO 2006/091663 to Tucker et al., the disclosure of which is fully incorporated by reference herein. Suitable materials include polycarbonates, polyurethanes, poly(meth)acrylates, polypropylenes, polyethylenes including low density polyethylene, linear low density polyethylene, medium density polyethylene, high density polyethylene, very low density polyethylene and ultralow density polyethylene, ethylene/α-olefin copolymers, styrene-acrylonitrile copolymers, polyethylene terephthalates, and polybutylene terephthalates.

In one embodiment, the container are comprised of a lightly crosslinked thermoplastic, such as described in U.S. Pat. No. 6,248,832 to Peacock, and incorporated in its entirety herein. The thermoplastic can be a blend of isotactic polypropylene segments and atactic polypropylene segments with sufficient crosslinking via diene incorporation into both types of segments to produce the crosslinked thermoplastic. Polymer or polypropylene segments, as used herein, are intended to refer to copolymers containing the selected diolefin monomers as a minor constituent. The crosslinked final composition contains a mixture of linkage types via incorporation of single diolefin monomers into two separate polymer segment. These linkage types include connections between two amorphous copolymer segments, connections between two crystalline copolymer segments, and connections between amorphous copolymer segments and crystalline copolymer segments. The diolefin monomer(s), preferably di-vinyl monomer(s), are added to the reaction medium in an amount sufficient to produce a detectable amount of crosslinking but are limited to an amount such that the final composition remains thermoplastic. Additionally, an elastomer may be crosslinked during melt processing of a thermoplastic, for example the dynamic vulcanization of PP-EPDM blends. The materials formed are called thermoplastic vulcanizates, where the elastomer forms small particles vulcanized and dispersed in the polypropylene matrix.

The suitable material for use as the object to be coated in the present invention comprises a polypropylene component. The polypropylene component can be high crystalline polypropylene (such as those described in WO 2004/033509, which is hereby incorporated by reference in its entirety), homopolymer polypropylene, a random copolymer of propylene and an alpha olefin having 2 carbon atoms and/or from 4 to 12 carbon atoms, an impact copolymer polypropylene or a reactor grade propylene based elastomer or plastomer (such a s those described in WO2003/040201, which is hereby incorporated by reference in its entirety). These polypropylene materials are generally well-known in the art. It is also contemplated that the object to be coated may comprise two or more of these materials blended or otherwise combined together. Suitable polypropylene components include those polypropylene materials described in WO2006/12156, which is hereby incorporated in its entirety. Furthermore in some situations, it may be beneficial to include an amount of an ethylene-alpha-olefin copolymer with the polypropylene material (s), where the alpha-olefin has from 3 to 12 carbon atoms and the ethylene-alpha olefin component and the polypropylene component are blended prior to extruding and injecting the molten polypropylene resin into the mold (either the pre-mold or the object mold). Suitable alpha olefins for use as the comonomer in such materials include 1-octene, 1-hexene and 1-butene.

Nanometer sized fillers such as nano-tubes, nano-fiber, nano-particles and especially delaminated or exfoliated cation exchanging layered materials (such as delaminated 2:1 layered silicate clays) can be used as a reinforcing filler in a polymer system. Such polymer systems are known as “nanocomposites” when at least one dimension of the filler is io less than sixty nanometers and when the amount of such filler is in the range of from 0.1 to 50 weight percent of the nanocomposite. Nanocomposite polymers generally have enhanced mechanical property characteristics vs. conventionally filled polymers. For example, nanocomposite polymers can provide both is increased modulus and increased impact toughness, a combination of mechanical properties that is not usually obtained using conventional fillers such as talc. When delaminated or exfoliated cation exchanging layered materials are to be used as the nanometer sized fillers, maleated polymer (such as maleated polypropylene) is often blended into a polymer system to increase the degree of delamination of the cation exchanging layered material. As discussed in detail in EP1268656 (WO 01/48080) an important sub-class of nanocomposite polymers is nanocomposite thermoplastic olefin. Thermoplastic olefin, also termed “TPO” in the art, usually is a blend of a thermoplastic, usually polypropylene, and a thermoplastic elastomer. A nanocomposite TPO is formed when the thermoplastic of the TPO contains the nano-filler. Suitable nano-fillers are silicates and other fillers such as Magadiite, Kenyalte, smectites, hormites, vermiculites, illites, micas, and chiorites, Biophilite, kaolinite, dickalite, talcs, Semectites, Vermiculites, Micas, Brittle micas, Octosilicates, Kanemites, Makatites, and Zeolitic layered materials.

The container structure can include at least a first bulk layer comprising commodity polyolefinic resin. Polyolefinic materials are not very resistant to macromolecular penetration of fats, oil, and other chromophoric chemical species, such as lycopene in tomato-based foods. Polyolefins trap stains and odor of which a consumer may find obtrusive in a container intended for re-use. Therefore coating this material with SiOx imparts the improved stain-resistance. Adhesion of the SiOx coating to the molded container may be enhanced through use of a layer that provides an inner container wall substrate surface that has improved chemical or mechanical affinity for the SiOx coating. Although the layer material provides an important performance attribute, materials of this nature can sometimes be exorbitantly expensive and thus the manufacturer of limited-reuse containers should be vigilant in formulating structures so as to minimize the use of these materials for economic reasons. As such, this layer should be oriented so as to reside only on the food contact surface of a thermoformed container, and at a minimum thickness that serves effective in enhancing performance. Because the ratio of post-process scrap material (reclaim) to final product is very high in the manufacture of containers, the use of reclaim is of fundamental importance to an economically viable molding operation. As such, the pre-coated structure of this invention may include a third reclaim layer located between the first and second layer comprising a mixture of two (2) reclaimed resin components: a polyolefin component as in the first bulk layer and a tie layer component as found in the second layer. In this case, the first bulk layer will be located on the exterior wall of the container to cap the third reclaim layer. Optionally, the first layer may be simply formulated to include the reclaim components, thus comprising a two-layer structure consisting of bulk layer containing reclaim with a tie layer on the inner surface of the container.

In one embodiment, the container is coated using a treatment of three process gases, a pretreatment with nitrogen gas, treatment with a mixture of hexamethyldisiloxane in oxygen, and a post-treatment with oxygen gas. Gases for pretreatment, treatment, or post-treatment include oxygen, nitrogen, nitrous oxide and mixtures thereof.

Suitable working gases include vinylalkoxysilane, vinylalkylsilane, vinylalkylalkoxysilane, allyalkoxysilane, allylalkylsilane, allylalkylalkoxysilane, alkenylalkoxysilane, alkenlyalkylsilane, alkenylalkylalkoxysilane and mixtures thereof.

Examples of suitable working gases include organosilicon compounds such as silanes, siloxanes, and silazanes. Examples of silanes include tetramethylsilane, trimethylsilane, dimethylsilane, methylsilane, dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane (also known as tetraethylorthosilicate or TEOS), dimethoxymethylphenylsilane, phenyltrimethoxysilane, 3-glycidoxypropyltrimethoxysilane, glycidoxypropyltrimethoxysilane, 3-methacrylpropyltrimethoxysilane, diethoxymethylphenylsilane, tris(2-methoxyethoxy)vinylsilane, phenyltriethoxysilane, and dimethoxydiphenylsilane. Examples of siloxanes include tetramethyldisiloxane, hexamethyldisiloxane, and octamethyltrisiloxane. Examples of silazanes include hexamethylsilazanes and tetramethylsilazanes. Siloxanes are preferred working gases, with tetramethyldisiloxane (TMDSO) being especially preferred. Useful working gases include other siloxanes, fluorocarbons, such as carbon tetrafluoride (CF₄), perfluorotetradecane; aromatic fluorohydrocarbons such as fluorobenzene; benzotrifluorides such as 3-(trifluoromethyl)benzyl alcohol; fluoroalkenes/alkynes such as hexafluoropropene trimer; (Meth)acrylate monomers such as hexafluoroisopropyl acrylate; fluoroalcohols and phenols such as hexafluoroisopropanol; fluorine-containing ethers such as trifluoromethoxy benzene; fluorine-containing ketones such as hexafluoracetone; fluoroacids and anhydrides such as difluoroacetic acid; fluoroaldehydes such as pentafluorobenzaldehyde; fluoroesters such as ethyl trifluoroacetate; fluorine containing nitriles such as pentafluorobenzonitrile; inorganic fluorine compounds such as silver fluoride; and fluorine-containing silanes such as trimethylfluorosilane.

The polymeric structure of the container can be either a mono-layer or multi-layer coextruded sheet produced through conventional coextrusion means, or a mono-layer or multi-layer structure manufactured by injection-molding, injection over-molding, or in-mold labeling. The sheet and/or resin is molded into three dimensional container articles and then coated to impart stain resistance to the container's interior food contact surface. The coating process can be any conventional coating means, including but not limited to sputtering, evaporative deposition, and CVD (Chemical Vapor Deposition). Preferably the coating process employs PECVD (Plasma Enhanced Chemical Vapor Deposition). The stain-resistant coating imparted by these processes usually comprises a glass-like silicon dioxide (SiOx) type coating but may also include SiOCH coatings where carbon and hydrogen are included in the SiO crystal lattice structure of the coating to provide performance enhancements as per U.S. Pat. No. 5,298,587. Optionally, the SiOx coating can also include other elemental species such as fluorine to impart enhanced performance as per U.S. Pat. No. 6,015,595. Herein, the term SiOx will be used to describe any combination of these coating compositions, including multiple layers of these coating compositions. In fact, the stain-resistant coating can comprise any material characterized by high resistance to macromolecular penetration of fats, oils, and other chromophoric chemical species.

As these and other variations and combinations of the features discussed above can be utilized without departing from the present invention, the foregoing description of the preferred embodiments should be taken by way of illustration rather than by way of limitation of the present invention as defined by the claims. The following examples are intended to further illustrate the invention, but not to limit it.

### EXAMPLES

### Example 1

### Effect of Coating Thickness on RuO4-Stained % Transmission

Natural (not colored) 24 oz rectangular thermoformed polypropylene containers, tub portion, not including lid, were coated with SiOx utilizing plasma enhanced chemical vapor deposition (PECVD) deposition apparatus as described herein. The tubs comprised a homogenous homopolymer polypropylene blend of virgin resin and up to 70% in-plant reclaim. The homopolymer is a 2.0 melt flow, 0.905 density, nucleated homopolymer polypropylene with a flexural modulus of 230,000 psi. A linear organosilicon starting material (hexamethyldisiloxane) was combined with oxygen in a plasma generated at 13.56 MHz to deposit the thin films preferentially on the inside food contact surfaces of the container.

Prior to deposition, the container was exposed to nitrogen plasma. Post-deposition, the coating was exposed to oxygen plasma. Key parameters of the coating process are summarized in Table 1.

TABLE 1

| | N2 Gas | HMDSO gas | O2 gas | | |
|---|---|---|---|---|---|
| Treatment | flow rate, | flow rate, | flow rate, | Power | Duration |
| Step | sccm | sccm | sccm | (Watts) | (seconds) |
| Pre- | 50 | none | none | 500 | 10 |
| treatment | | | | | |
| Coating | none | 7.5 | 70 | 500 | Variable (1) |
| Deposition | | | | | |
| Post- | none | none | 70 | 500 | 10 |
| treament | | | | | |

(1) Duration dependent on desired coating thickness where deposition rate was generally about 10 nm per second.

The basic equipment configuration used for all coatings is shown in FIG. 13, showing heater 300, the gas inlet 302, the pumping plenum 304, the reactor wall 306, the container 308, the insert 310 and the mandrel 312 holding the insert 310 in place. The gas inlet could accommodate several gas options, including a nitrogen gas pre-treatment, a treatment gas of hexamethyldisiloxane and oxygen, and a oxygen gas post-treatment. The focus was to coat the interior of the tubs, but there may have been some plasma generated outside of the container. It is not critical to only have plasma inside of the container. Using this configuration, five (5) containers were coated at each coating thickness of 35, 53, 70, 86, 112, 120, and 150 nm as determined by profilometer. The coating thickness was characterized with a Dektak 2A profilometer on glass slides that were coated as witness samples, where the witness sample was attached to the inside tub wall with adhesive tape and it remained through the coating process. The tape was used to mask part of the glass slide so that the profilometer could measure the step change in thickness between the coated section and masked, uncoated section. Similarly, a silicon witness sample(s) was placed near the glass slide, whereby the physical thickness could be compared to the intensity of the Si—O—Si stretch peak intensity (1052 to 1054 cm-1) as measured by Fourier Transform Infra Red Spectroscopy (FTIR). It can be said that in addition to characterizing SiOx coating thickness given the direct proportionality between coating thickness and stretch peak intensity, FTIR spectra also can provide coating composition information. In this case, Si—CH3 (1260 cm-1) was not detected at any significant levels in any of the coatings indicating that the coating composition was substantially SiOx.

For each coating thickness five (5) tub specimens were produced. One (1) tub specimen included a glass slide and three (3) silicon chips attached as witness samples and this specimen was dedicated to determinations of coating composition by FTIR and thickness by profilometer. Four (4) tub specimens were coated for testing purposes. Of the four coated tubs, one was used as a reference for optical transmission measurements. The efficacy of the deposited SiOx coating of the remaining three (3) tubs was tested by filling to 80% volumetric capacity with tomato soup, heating the contents in a conventional microwave oven to boiling (approx. 2 minutes), and then discarding contents and cleaning the container thoroughly by rinsing and wiping with sponge and mild detergent to loosen residual food contents prior to dishwashing in a conventional commercial dishwasher.

The microwave/dishwasher-treated containers were then tested to determine if the coating had survived by staining with Ruthenium Tetraoxide as per Trent, J. S., Scheinbeim, J. I., Couchman P. R., Ruthenium Tetraoxide Staining of Polymers for Electron Microscopy, Macromolecules, 16, 589-598, (1983). The Ruthenium-based stain attacks the polypropylene turning it black. The stain cannot attack a SiOx coating, so if the container is uniformly coated and the coating remains 100% conformal with no cracking, damage or delamination after the microwave/dishwasher treatment, the container will not absorb the stain and will remain transparent. If the coating is cracked, damaged or delaminated, the stain will penetrate these areas and turn the PP black, reducing its optical transmission.

Once stained and stored for five (5) hours, the samples were neutralized with water and then allowed to dry. The samples were then placed into a transmission measurement device (using white light) to determine the amount of stain that was absorbed into the polypropylene. The apparatus that was used to measure the transmission is illustrated in FIG. 14, showing the container 402, the light source 404, the fiber optic light collector 406, and the optical sensor 408.

The following procedure was used to measure each container:

1. Install reference container (coated but not microwave/dishwasher tested or stained).
2. Average up to 40 scans—record average count (at center peak).
3. Repeat #2 three times removing and re-installing container into optical fixture.
4. Install first stained container (coated under same condition as reference).
5. Repeat #2 and #3 above.
6. Install second stained container (coated under same condition as reference).
7. Repeat #2 and #3 above.
8. Install third stained container (coated under same condition as reference).
9. Repeat #2 and #3 above
10. Take the average of all of the measurements from #5, #7 and #9 above.
11. Divide the value from #10 above by the value in #3—this is the optical transmission and will be less than or equal to 100%. The lower the number, the more stain that was absorbed into the PP and the less effective the SiOx coating.

Following the above procedure, the measurement error (for the testing apparatus) was determined to be approximately 1% (0.095) of the measurement. Based on the above procedure, Table 2 summarizes the effect of coating thickness on % transmission for the varying thickness samples:

TABLE 2

| Coating Thickness (nm) | % Transmission |
|---|---|
| 150 | 95% |
| 120 | 93% |
| 112 | 93% |
| 86 | 95% |
| 70 | 87% |
| 53 | 79% |
| 35 | 45% |

It is clear from Table 2 that the coating begins to degrade around 80 nm and falls off significantly below 50 nm. The significant deterioration at 35 nm can be clearly seen in the stained containers. The optimal range for the coating appears to greater than 35 nm, and preferably greater than about 50 nm. But, for actual implementation, a thicker coating (on the order of 100 nm) could be advantageous since it will be more robust and might better withstanding wiping and scouring.

### Example 2

### Effect of Pre-Treat and Post-Treat on RuO4-Stained % Transmission

In order to estimate the importance of combining the pre-treatment step using nitrogen gas and post-treatment step using oxygen gas along with the coating deposition step, a designed experiment was developed utilizing the process parameters as provided earlier in Table 1 to coat thermoformed PP tubs identical to those tubs described in Example 1. The designed experiment was completed in a similar manner as the thickness experiment, coating five (5) tub samples per condition. The only difference was that all samples were produced at a coating thickness of approximately 100 nm. The coating deposition step duration was approximately 10 seconds for each experimental treatment combination. The samples were then treated using the microwave/dishwasher procedure outlined in Example 1 and then measured using the same RuO4 staining and light transmission procedure outlined in Example 1. Table 3 summarizes the experimental factors and averaged % transmission result of each treatment A-F.

TABLE 3

| Treatment Label | N2 Pre-treat? | O2 Post-treat? | % Transmission |
|---|---|---|---|
| A | YES | NO | 98% |
| B | NO | YES | 85% |
| C | YES | YES | 100% |
| D | NO | YES | 86% |
| E | NO | NO | 79% |
| F | NO | NO | 79% |

Treatments E and F, which included no pre-treatment and no post-treatment, produced containers with significant staining. The % transmission was lower for these samples indicating the containers were darker due to relatively poor stain resistance. The above data was analyzed using SAS JMP 6.0 software. Both pre-treatment and post-treatment were found to be statistically significant by the software. In comparing Treatment A to Treatments E and F, it is clear that the nitrogen pre-treatment alone is significant. Likewise, in comparing Treatment B to Treatments E and F, it is clear that the oxygen post-treatment alone is significant. The combination of both the nitrogen pre-treatment and oxygen post-treatment produces containers with the best performance, as in Treatment C. Separately, the FTIR peak intensity results for 100 nm coated samples was consistent indicating uniform coating thickness and composition, as FTIR absorption of the Si—O—Si peak ranging from 0.075-0.078 and Si—O—Si peak positions ranging from 1052-1054 cm-1. Again, Si—CH3 (1260 cm-1) was not detected at any significant levels in any of the coatings indicating that the coating composition was substantially SiOx.

### Example 3

### Effect of SiOx Coating on Performance of Containers with HPP Monolayer and 2-Layer Coextruded Sheet Constructions

In order to estimate the importance of substrate type on overall durability of the uncoated and SiOx-coated containers exposed to microwave re-heating of chili, several different sheet structures/compositions were used to thermoform the rectangular containers of identical design as that described in Examples 1 and 2. A portion of these samples were tested without PECVD coating, and a complimentary portion of these containers were coated with 100 nm thick SiOx by combining the pre-treatment step using nitrogen gas and post-treatment step using oxygen gas along with the coating deposition step as per the process parameters provided earlier in Table 1.

The containers were thermoformed from single layer and 2-layer coextruded sheet structures as listed in Table 4. The table describes the resin composition of each layer, the layer ratio, the overall sheet thickness prior to thermoforming, and whether the specific treatment was coated with SiOx. The A-layer comprised the inside food contact surface that was the intended substrate for coating as designated.

TABLE 4

| | | | | pre- | |
|---|---|---|---|---|---|
| | | | | forming | |
| | A-layer | | | sheet | |
| | composition | | | thick- | SiOx |
| Treat- | (intended | | A:B layer | ness | coat- |
| ment | substrate) | B-layer composition | ratio | (inch) | ing? |
| 1 | 100% HPP | none | monolayer | 0.052 | NO |
| 2 | 100% HPP | none | monolayer | 0.052 | NO |
| 3 | 100% HPP | none | monolayer | 0.052 | YES |
| 4 | 100% HPP | none | monolayer | 0.052 | YES |
| 5 | 100% virgin | 25% virgin HPP + | 20:80 | 0.052 | NO |
| | HSPP | 37.5% simulated re- | | | |
| | | claim HPP + 37.5% | | | |
| | | simulated reclaim | | | |
| | | HSPP | | | |
| 6 | 100% virgin | 25% virgin HPP + | 20:80 | 0.052 | YES |
| | HSPP | 37.5% simulated re- | | | |
| | | claim HPP + 37.5% | | | |
| | | simulated reclaim | | | |
| | | HSPP | | | |
| 7 | 100% HSPP | none | monolayer | 0.048 | NO |
| 8 | 100% HSPP | none | monolayer | 0.048 | YES |
| 9 | 80% HSPP + | 100% HPP | 10:90 | 0.052 | NO |
| | 20% VLDPE | | | | |
| 10 | 80% HSPP + | 100% HPP | 10:90 | 0.052 | YES |
| | 20% VLDPE | | | | |

In Table 4, HPP refers to homopolymer polypropylene (2.0 melt flow, 0.900 density, flexural modulus 230,000 psi, Heat Deflection Temperature, HDT 217° F., including a nucleation agent). HSPP refers to high stiffness polypropylene (3.0 melt flow, 0.900 density, flexural modulus 300,000 psi, HDT 264° F., including a nucleating agent). VLDPE is very low density polyethylene, a substantially linear ethylene polymer with high levels of short chain branches made by copolymerizing ethylene with alpha-olefins (1.0 MI, 0.902 density). HSPP and VLDPE typically cost more than HPP and as a result their use should be minimized for economic reasons.

The sheet structures specified in Treatments 1-4 represent conventional polypropylene food containers. The alternative sheet structures specified in Treatments 5-10 demonstrate the use of substrates that enhance durability of the SiOx-coated containers exposed to microwave re-heating as measured by resistance to sidewall warpage and resistance to melt pitting, both deleterious issues that polypropylene containers are subject to upon exposure to excessive temperatures. Additionally, Treatments 5-8 in this example demonstrate practical considerations to avoid excessive costs. For instance, Treatments 5-6 include the more costly HSPP as an intended substrate for coating (Layer A) but its use in the overall structure is reduced by judicious incorporation as a minor layer. Additionally, in Treatment 5-6, the practical consideration of steady-state consumption of 60% in-plant reclaim, typical of thermoforming operations, is demonstrated as major Layer B comprises mainly the less costly HPP and comprises an overall ratio of HPP/HSPP that satisfies steady state reclaim usage. Layer B includes HPP from in-plant reclaim and added virgin HPP to satisfy the overall mass balance. Layer B also includes a minor portion of HSPP as reclaim. Treatments 7-8 were included to demonstrate enhanced performance of HSPP at reduced overall sheet thickness relative to Treatments 1-4, as this represents another way to include performance enhancing material at reduced cost.

To evaluate substrate type and efficacy of the deposited SiOx coating on durability after microwave heating of chili using thermoformed containers as described in Table 4, a quantity of six (6) containers of each treatment were tested as follows. The 24 oz containers were filled to 50% capacity (contents 12 fl oz) with Campbell's Chunky Fully Loaded Beef and Bean Chili. The filled containers were heated to boiling in a conventional 1100 watt microwave for 2 minutes at a power setting of 100%. The food content was discarded and the containers were cleaned thoroughly by rinsing and wiping with sponge and mild detergent to loosen residual food contents prior to dishwashing in a conventional dishwasher.

After this treatment samples exhibited various degrees of staining, melt-pitting, and sidewall warpage. Some samples exhibited noticeable orange-colored staining on the tub sidewalls just below the 50% capacity fill line or meniscus. Some samples exhibited noticeable melt pitting generally scattered at and above the meniscus, where melt pitting can be described as small white and orange-colored discontinuous areas of irregular shape and size, indicating that the normally translucent polymer surface was melted and etched by the highly heated food contents. At such points the surface lacked clarity, was no longer smooth, and may have been penetrated by embedded food contents. Some samples exhibited noticeable sidewall warpage indicated by wavy deformation.

Table 5 shows the performance results of each Treatment type listed in Table 4, as characterized by CIELAB colorimeter values, melt-pitting rating, and warpage rating.

The CIELAB colorimeter values were measured using a BYK Gardner Model 6834 Spectro-Guide spectrophotometer to measure spectral reflectance within the visible spectrum of wavelengths from 400-700 nm as per ASTM D2244 with Illuminant/Observer D65/10°. The measurements were made using a circular aperture of diameter 0.438 inches at the midline of the sidewall with the upper edge of the aperture located ⅛ inch below the meniscus. The sidewall was backed with a white reference tile with the color values, L*=86.5, a*=0.38, b*=1.20. The three coordinates of CIELAB represent the lightness of the color (L*=0 yields black and L*=100 indicates diffuse white), its position between red/magenta and green (a*, negative values indicate green while positive values indicate magenta) and its position between yellow and blue (b*, negative values indicate blue and positive values indicate yellow). Since the staining on the containers appears orange-colored to the human eye, one would expect that more strongly stained containers would exhibit lower L* values (indicating relative darkening), more positive a* values (indicating more magenta), and more positive b* values (indicating more yellow) as compared to an uncolored natural translucent container. Per each tub specimen, two measurements were made, one on each opposing long sidewall of the rectangular container.

The melt pitting and warpage ratings are averaged qualitative visual observations made by a plurality of judges. The rating scales for melt pitting and warpage are listed in Tables 6 and 7, respectively. For both melt pitting and warpage, high ratings indicate superior performance.

TABLE 5

| | CIELAB Colorimeter D65/10° | | | | |
|---|---|---|---|---|---|
| Treat- | L*- | a*- | b*- | melt pitting | warpage |
| ment | value | value | value | rating | rating |
| 1 | 79.8 | 5.5 | 14.9 | 3.4 | 2.0 |
| 2 | 80.2 | 4.7 | 12.5 | 3.2 | 2.5 |
| (repeat 1) | | | | | |
| 3 | 83.0 | 0.4 | 2.6 | 4.2 | 2.2 |
| 4 | 83.1 | 0.4 | 2.7 | 5.0 | 2.3 |
| (repeat 3) | | | | | |
| 5 | 80.4 | 4.5 | 11.5 | 5.4 | 2.7 |
| 6 | 82.4 | 0.4 | 2.6 | 5.7 | 3.0 |
| 7 | 80.1 | 2.8 | 8.1 | 4.6 | 3.0 |
| 8 | 82.5 | 0.5 | 2.7 | 5.8 | 3.0 |
| 9 | 74.4 | 11.4 | 28.8 | 7.7 | 3.0 |
| 10 | 80.6 | 0.9 | 3.7 | 7.2 | 3.0 |

TABLE 6
MELT PITTING Visual Rating Scale (1-10)

```
10—No noticeable pitting.
  9—Isolated very light pitting.
  8—Very light pitting.
  7—Light pitting.
  6—Light/Moderate pitting all around.
  5—Moderate/Intermediate pitting isolated to one area, light
pitting elsewhere.
  4—Scattered intermediate pitting.
  3—Continuous intermediate pitting, isolated heavy pitting.
  2—Interrupted heavy pitting.
  1—Continuous heavy pitting.
```

TABLE 7
WARPAGE Visual Rating Scale (1-3)

3—No warpage evident.
2—Slightly/partial warpage.
1—Heavy warpage.

Upon examination of the results in Table 5, it can be seen that the presence of the SiOx coating on Treatments 3, 4, 6, 8, and 10 were very effective at reducing orange-colored staining, as indicated by relatively high L* values, and low a* and b* values that approach the white background tile reference values. In contrast, Treatments 1, 2, 5, 7, and 9 exhibit the opposite effect indicating strong staining. The efficacy of the SiOx coating in preventing staining is especially evident by comparing Treatments 9 and 10 comprising identical inner food contact layers (substrates) comprising 80% HSPP and 20% VLDPE. Without being bound by any one theory, it is thought that the VLDPE portion of the substrate resin formulation is more easily penetrated by fats, oils, and, chromatic chemical species such as keratinous substances in tomato-based foods, therefore this type of substrate will stain more readily than 100% HSPP or 100% HPP substrates as demonstrated in the remaining uncoated treatments. However, after coating the VLDPE containing substrate with SiOx the resistance to staining is adequately improved.

Furthermore, by comparing coated and uncoated treatment pairs employing identical substrates (Treatments 1, 2 vs 3, 4; Treatment 5 vs 6; Treatment 7 vs 8) the SiOx coating is generally effective at improving melt pitting performance when employed.

The choice of substrate can greatly affect melt pitting performance. Table 5 shows that when employing 80% HSPP and 20% VLDPE, melt pitting is significantly reduced regardless of whether the substrate is coated or uncoated with SiOx. Without being bound by any one theory, it is thought that this effect results from increased substrate viscosity at low shear conditions and/or improved substrate melt elasticity, whereby the improvement in these properties occurs at or above the melting point of the matrix polymer, this temperature being encountered given the localized condition at the container sidewall while heating oil based foods in the microwave. This performance enhancement is not provided in a substrate that does not contain VLDPE or any other such modifier that would behave similarly to increase viscosity and/or improve melt elasticity compared to unmodified base polymer, thereby melt pitting occurs more frequently in this case given an identical elevated temperature/low shear condition as that in microwave heating of fatty foods. As such the unmodified base polymer substrate melts and more readily flows, ultimately resulting in a higher degree of surface deformation observable upon inspection of the washed container.

The choice of substrate can greatly affect warpage performance. Table 5 shows that when employing either 100% HSPP or 80% HSPP and 20% VLDPE versus 100% HPP, warpage is significantly reduced owing to the presence of the higher stiffness polymer, HSPP, which offers improved heat deflection temperature versus conventional HPP. In fact, this performance improvement exists even in treatments that include 100% HSPP as a minor food contact layer substrate but includes a bulk layer containing less costly HPP and reclaim (Treatments 5, 6), and also in monolayer 100% HSPP treatments that have been down weighted for economic reasons (Treatments 7, 8).

The importance of increasing melt elasticity as a means of reducing melt pitting during microwave heating of foods was explored by measuring melt elasticity of the substrate resins. Recoverable strain of the melted substrates was measured by the Melt Elasticity Indexer (CSI-245, Custom Scientific Instruments). The Melt Elasticity Indexer is an instrument measuring recoverable strain on a melt specimen allowed to return to its original position following a controlled deformation. A cup member is fixed to the frame of the apparatus and is enclosed in a heating element. Inside the cup is a cylindrical rotor mounted coaxially with the cup. The specimen of the polymer to be tested is located in the annular region between the rotor and the inside of the cup. The heater brings the specimen to the desired test temperature which is maintained by a thermocouple and controller. The rotor is turned about its axis by a mechanical drive system to apply the deformation or required amount of strain. When then desired strain has been reached the drive system is released. The rotor is then free to rotate about its axis. The stored elastic energy in the melt specimen turns the rotor as the elastic recovery takes place. This is the recoverable strain due to melt elasticity. The initial recovery (turning of the rotor) is quite rapid and then slower until recovery is finished. To monitor strain recovery the rotor has mounted to it a scaled disk to determine the amount of rotation that has taken place. The sheer field in the Melt Elasticity Indexer is called the Couette Geometry. Since the diameter of the inside of the cup is 0.25 inches and the diameter of the outside of the rotor is 0.1875 inches, then one Strain Unit is defined as 16.4 degrees of rotation. A Melt Elasticity Index (MEI) is defined as the amount of recovery that takes place after a specified time period. The MEI values of the substrates were measured at 230 degC, where the deformation was controlled at 1.0 Strain Unit (SU) per second with total strain of 6 SU.

Table 8 reports the MEI values of the resins that were used as inside food contact layer substrates during manufacture of the containers shown in Table 4 and identified as Treatments 1-10. This data confirms that the MEI of a substrate comprising 80% HSPP and 20% VLDPE (Treatments 9-10) is higher than either HPP (Treatments 1-4) or HSPP (Treatments 5-8) when used alone. The addition of 20% VLDPE boosts the elasticity of the melt to a value of 0.87 SU @ 10 seconds, which is greater than about 0.67 SU @ 10 seconds as compared to HPP (test conditions: 230 degC at a strain rate of 1 SU per second over a total strain of 6 SU). This testing was done at 230 degC which is well above the Differential Scanning calorimeter (DSC) Melting Point of 160 degC typical of polypropylene homopolymer. The result is surprising because VLDPE of density 0.902 g/cm3 typically exhibits a DSC MP of about 100 degC, therefore one would expect that addition of VLDPE to homopolymer polypropylene would decrease the elevated temperature performance of the container when compared to homopolymer polypropylene alone.

A helpful discussion on understanding the nature of melt elasticity can be found in Melt Elasticity, Bryce Maxwell, Professor Emeritus, Dept of Chemical Engineering, Princeton University, 1988. A polymer melt comprises long chain molecules that coil and uncoil in a random manner. There is continuous motion of small chain segments and large chain segments. Cohesive forces of a secondary nature form between chains as interaction points that very in degree of permanence. Cross-linking is an example of a more permanent interaction point that acts to improve strain recovery. When polymer melt is strained, the chain segments orient to some degree in the direction of the deformation. This causes them to be stretched from their normal configuration. A driving force exists causing the chain segments to recoil when the deforming force is removed. This is elastic recovery. However, uncoiling of molecules requires that some segments slip past each other, and increases in this resistance lead to higher internal viscosities which prevent instantaneous recovery. Elastic strain recovery in the melt is dependent on the retractive force stored in uncoiled molecular segments between interaction points, the permanence of the interaction points, and the internal viscosity. These factors are influential in devising methods to improve melt elasticity and thereby container melt-pitting performance. Melt elasticity can be improved though a number of means used alone or in combination to increase the potential for chain entanglement, including increased polymer molecular weight, increased chain branching of polymer long chain backbone molecules, by cross-linking, by co-polymerization involving co-monomers randomly or introduced as blocks of repeating co-monomeric units, or by blending more polymers with greater inherit elasticity into those with less elasticity. Based on the measurements made in Table 8, it can be concluded that any of these techniques can be used to improve melt elasticity of the container materials in order to decrease the occurrence of melt pitting of the inside wall of the container during microwave heating of foods. In fact it is preferred that MEI at 230 degC at a strain rate of 1 SU per second over a total strain of 6 SU should be greater than about 0.67 SU @ 10 seconds in order to offer improved melt pitting resistance as compared to containers made using unmodified homopolymer PP

TABLE 8
Melt Elasticity Index Measurements on A-layer Substrates

| | A-layer | Melt Elasticity Index, 230 C., | | | |
|---|---|---|---|---|---|
| | composition | 1 SU/second, Total: 6 SU | | | |
| | (intended | @ | @ | @ | @ |
| Treatment | substrate) | 1 sec | 2 sec | 5 sec | 10 sec |
| 1-4 | 100% HPP | 0.48 | 0.56 | 0.60 | 0.59 |
| 1-4 | 100% HPP (repeat) | 0.50 | 0.58 | 0.67 | 0.67 |
| 5-8 | 100% HSPP | 0.40 | 0.49 | 0.58 | 0.61 |
| 9-10 | 80% HSPP + | 0.51 | 0.63 | 0.78 | 0.87 |
| | 20% VLDPE | | | | |

Thus, the invention is limited only by the following claims.

We claim:

1. An apparatus for forming a coating on an interior surface of a container having a container bottom and a top opening, the apparatus comprising:
a chamber having only one open side and made of an electrically insulating material, the chamber for enclosing the container;
an insert for holding the container bottom and baffle plate for sealing the container top opening;
a removable lid assembly having an inlet or inlets for one or more counter electrodes,
a gas inlet or inlets, and a pumping plenum connecting a vacuum pump, the removable lid assembly capable of forming a vacuum seal on the chamber open side; and
a main electrode assembly adjacent to a closed exterior surface of the chamber opposite the lid assembly, wherein the main electrode assembly comprises a main electrode enclosed between an upper embedding slab adjacent to the closed exterior surface of the chamber opposite the lid assembly and a lower embedding slab.

2. The apparatus of claim 1, wherein the gas inlet or inlets comprises a first gas component source; a second gas component source comprising an organosilicon material, and a third gas component source and wherein said gas inlet or inlets are fluidly connected to the counter electrode.

3. The apparatus of claim 1, wherein the removable lid assembly is part of a coating station and the chamber is attached to guide shafts for movement out of the coating station.

4. The apparatus of claim 1, wherein the removable lid assembly is attached to guide shafts to move the removable lid assembly to an open position relative to the chamber from a closed vacuum position relative to the chamber.

5. The apparatus of claim 2, wherein the removable lid assembly has a vent port capable of being connected to a vent valve and a pressure port capable of being connected to a pressure measuring device.

6. The apparatus of claim 2, wherein the counter electrode is a hollow tube.

7. The apparatus of claim 1, wherein one of the gas inlets is connected to a gas nozzle by a gas nozzle connector where both the gas nozzle and the gas nozzle connector are or electrically conductive materials.

8. The apparatus of claim 7, wherein the gas nozzle and gas nozzle connector form the counter electrode.

9. The apparatus of claim 1, wherein there is a side detent between the bottom inside of the chamber and the side of the main electrode assembly.

10. The apparatus of claim 1, wherein the removable lid assembly has multiple inlets for counter electrodes.

11. An apparatus for forming a coating on an interior surface of a container having a container bottom and a top opening, the apparatus comprising:
a chamber having only one open side and made of an electrically insulating material, the chamber for enclosing the container;
a removable lid assembly having an inlet or inlets for one or more counter electrodes,
a gas inlet or inlets, and a pumping plenum connecting a vacuum pump, the removable lid assembly capable of forming a vacuum seal on the chamber open side; and
a main electrode assembly adjacent to a closed exterior surface of the chamber opposite the lid assembly.

12. The apparatus of claim 11, wherein the main electrode assembly comprises a main electrode enclosed between an upper embedding slab adjacent to the closed exterior surface of the chamber opposite the lid assembly and a lower embedding slab.

13. The apparatus of claim 11, wherein the chamber contains an insert for holding the container bottom and baffle plate for sealing the container top opening.

14. The apparatus of claim 11, wherein the gas inlet or inlets comprises a first gas component source; a second gas component source comprising an organosilicon material, and a third gas component source and wherein said gas inlet or inlets are fluidly connected to the counter electrode.

15. The apparatus of claim 1, wherein the removable lid assembly is part of a coating station and the chamber is attached to guide shafts for movement out of the coating station.

16. A method of making a stain resistant container by forming a plasma deposited silica layer having high adhesion comprising:
(a) providing a base with an inside substrate surface comprising a thermoplastic polymer consisting essentially of a bottom, a peripheral sidewall extending from the bottom to create an inside and an outside, and an open top;
(b) treating the inside of the base with a plasma apparatus comprising the steps of:
(i) pre-treating the interior of the base with a plasma of nitrogen gas;
(ii) treating the interior of the base with a one-step organosilicon plasma treatment comprising an organosilicon compound in an atmosphere of greater than 85% oxygen gas to form a layer having a thickness of about 50-500 nm; and
(iii) post-treating the base with a plasma of oxygen gas only.

17. The method of claim 16, wherein the organosilicon compound is selected for the group consisting of a vinylalkoxysilane, a vinylalkylsilane, a vinylalkylalkoxysilane, an allyalkoxysilane, an allylalkylsilane, an allylalkylalkoxysilane, an alkenylalkoxysilane, an alkenlyalkylsilane, an alkenylalkylalkoxysilane and mixtures thereof.

18. The method of claim 16, wherein the organosilicon compound is hexamethyldisiloxane.

19. The method of claim 16, wherein the treatment step forms a layer of SiOx where x has a value less than 2.0 and the post-treatment step increases the value of x in SiOx to a value greater than 2.0.

20. The method of claim 16, wherein the thermoplastic polymer comprises a polypropylene component that is selected from the group consisting of high crystalline polypropylene, substantially polypropylene homopolymer, 100% polypropylene homopolymer, a random copolymer of propylene and an alpha olefin having 2 carbons and/or from 3 to 12 carbon atoms, an impact copolymer polypropylene, and blends of two or more thereof.
